(19) United States
(12) Patent Application Publication
(10) Pub. No.: US 2017/0090182 A1
(43) Pub. Date: Mar. 30, 2017

(54) SYSTEMS AND METHODS FOR REDUCING AMBIENT LIGHT REFLECTION IN A DISPLAY DEVICE HAVING A BACKPLANE INCORPORATING LOW-TEMPERATURE POLYCRYSTALLINE SILICON (LTPS) TRANSISTORS

(71) Applicant: Pixtronix, Inc., San Diego, CA (US)

(72) Inventors: Jasper Lodewyk Steyn, Cupertino, CA (US); Teruo Sasagawa, Los Gatos, CA (US); Takahide Kuranga, Mobara (JP)

(21) Appl. No.: 14/866,784

(22) Filed: Sep. 25, 2015

(51) Int. Cl. G02B 26/04; H01L 27/12

(52) U.S. Cl. CPC G02B 26/04; H01L 27/1259

(57) ABSTRACT

This disclosure provides systems, methods, and apparatus for reducing ambient light reflection in a display device having a backplane incorporating low-temperature polycrystalline silicon (LTPS) transistors. Ambient reflection can be reduced by incorporating both conductive and non-conductive light-absorbing materials into the display backplane. A light-absorbing conductive material that can withstand the temperatures generated by laser annealing of LTPS transistor channels can be deposited and patterned such that its footprint substantially coincides with the footprints of the LTPS channels. After the LTPS channels are fabricated, a light-absorbing dielectric material can be deposited with a footprint extending at least below the footprints of other reflective components of the backplane to be positioned above the light-absorbing dielectric material. Together, the light-absorbing conductive material and the light-absorbing dielectric material can obstruct substantially all of the reflective surfaces within the backplane, thereby reducing reflection of ambient light by the backplane.

### TECHNICAL FIELD

This disclosure relates to the field of imaging displays, and to display backplane architectures including low-temperature polycrystalline silicon (LTPS) transistors.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, or a combination of these or other micromachining processes that etch away parts of substrates, the deposited material layers, or both. Such processes also may be used to add layers to define electrical and electromechanical devices.

EMS-based display apparatus can display images by modulating light as it travels an optical path between opposing apertures in light blocking layers. EMS light modulators can be controlled by a backplane incorporating LTPS transistors.

### SUMMARY

The systems, methods and devices of this disclosure each have several innovative aspects, no single one of which is solely responsible for the desirable attributes disclosed herein.

One innovative aspect of the subject matter described in this disclosure can be implemented in a display apparatus. The display apparatus can include a transparent substrate having a viewing side and a second side opposite the viewing side. The display apparatus can include a backplane on the second side of the transparent substrate. The backplane can include a plurality of reflective components including at least a plurality of low-temperature polycrystalline silicon (LTPS) transistor channels. The backplane can include a light-absorbing dielectric layer positioned on a first side of the LTPS transistor channels farthest from the viewing side of the transparent substrate. The backplane can include a light-absorbing conductive layer positioned on a second side of the LTPS transistor channels opposite the first side, where the light-absorbing conductive layer has a footprint which includes a first portion that optically obstructs the plurality of LTPS transistor channels from the viewing side of the display.

In some implementations, the display apparatus can include a plurality of transistor gates included within the plurality of reflective components, and a plurality of source-drain terminals included within the plurality of reflective components. In some implementations, the light-absorbing dielectric layer can be positioned between the plurality of LTPS transistor channels and the plurality of source-drain terminals. In some implementations, portions of the light-absorbing dielectric layer can be on a side of the plurality of source-drain terminals farthest from the transparent substrate.

In some implementations, the light-absorbing dielectric layer can optically obstruct a portion of the reflective components included in the backplane from the viewing side of the transparent substrate. The footprint of the light-absorbing conductive layer can extend no more than about 10 microns beyond portions of the footprints of the respective reflective components optically unobstructed by the light-absorbing dielectric layer.

In some implementations, the reflective components of the backplane can have a footprint on the transparent substrate. The light-absorbing dielectric layer can optically obstruct a portion of the footprint of the reflective components from the viewing side of the transparent substrate leaving a portion of the footprint of the reflective components optically unobstructed from the viewing side of the transparent substrate. The light-absorbing conductive layer can have a footprint that substantially coincides with the portion of the footprint of the reflective components optically unobstructed by the light-absorbing dielectric layer.

In some implementations, the light-absorbing dielectric layer can be a planarizing layer. In some implementations, the light-absorbing dielectric layer can include dark spin-on-glass (DSOG). In some implementations, the light-absorbing dielectric layer can include a light-absorbing polymer material. In some implementations, the light-absorbing conductive layer can include at least one of molybdenum (Mo), titanium (Ti), tungsten (W), tantalum (Ta), carbon (C), and carbon black.

In some implementations, the light-absorbing dielectric layer can define a plurality of optical apertures each associated with a respective display element. In some implementations, the display elements can be MEMS shutter-based display elements. In some implementations, the display apparatus can include a second transparent substrate coupled to the transparent substrate and positioned on the second side of the transparent substrate, and a backlight positioned on a side of the second transparent substrate farthest from the transparent substrate.

In some implementations, the display apparatus can include a processor capable of communicating with the display apparatus. The processor can be capable of processing image data. The display apparatus also can include a memory apparatus capable of communicating with the processor. In some implementations, the display apparatus can include a driver circuit capable of sending at least one signal to the display apparatus, and a controller capable of sending at least a portion of the image data to the driver circuit. In some implementations, the display apparatus can include an image source module capable of sending the image data to the processor. The image source module can include at least one of a receiver, transceiver, and transmitter. The display apparatus also can include an input apparatus capable of receiving input data and communicating the input data to the processor.

Another innovative aspect of the subject matter described in this disclosure can be implemented in a method of manufacturing a display device. The method can include depositing and patterning a light-absorbing conductive layer on a transparent substrate on a side of the transparent substrate opposite a viewing side. The method can include depositing and patterning a plurality of low-temperature polycrystalline silicon (LTPS) transistor channels over the patterned light-absorbing conductive layer. The method can include depositing and patterning a light-absorbing dielectric layer over the patterned LTPS transistor channels. The patterned light-absorbing conductive layer can have a footprint that includes a first portion that optically obstructs the plurality of LTPS transistor channels from the viewing side of the display.

In some implementations, the method can include depositing and patterning a plurality of transistor gates over the LTPS transistor channels, and depositing and patterning a plurality of source-drain terminals over the LTPS transistor channels. In some implementations, the plurality of source-drain terminals can be deposited and patterned after the light-absorbing dielectric layer has been deposited and patterned.

In some implementations, the light-absorbing dielectric layer can be patterned to optically obstruct a portion of a set of reflective components included in the display device from the viewing side of the transparent substrate. The plurality of reflective components can include at least the LTPS transistor channels, the transistor gates, and the source-drain terminals. The light-absorbing conductive layer can be patterned such that its footprint extends no more than about 10 microns beyond portions of footprints of the reflective components that are optically unobstructed by the light-absorbing dielectric layer. In some implementations, the method can include depositing and patterning the light-absorbing dielectric layer after the plurality of source-drain terminals have been deposited and patterned.

In some implementations, the display device can include reflective components including the LTPS transistor channels, the source-drain terminals, and the transistor gates. The reflective components can have a footprint on the transparent substrate. The light-absorbing dielectric layer can be patterned to optically obstruct a portion of the footprint of the reflective components from the viewing side of the transparent substrate leaving a portion of the footprint of the reflective components optically unobstructed from the viewing side of the transparent substrate. The light-absorbing conductive layer can be patterned to have a footprint that substantially coincides with the portion of the footprint of the reflective components optically unobstructed by the light-absorbing dielectric layer.

In some implementations, the light-absorbing dielectric layer can be a planarizing layer. In some implementations, the light-absorbing dielectric layer can include dark spin-on-glass (DSOG). In some implementations, the light-absorbing dielectric layer can include a light-absorbing polymer material. In some implementations, the light-absorbing conductive layer can include at least one of molybdenum (Mo), titanium (Ti), tungsten (W), tantalum (Ta), carbon (C), and carbon black.

In some implementations, the method can include patterning the light-absorbing dielectric layer to define a plurality of optical apertures each associated with a respective display element. In some implementations, the method can include fabricating the display elements on a viewing side of a second transparent substrate facing the transparent substrate.

Another innovative aspect of the subject matter described in this disclosure can be implemented in a display apparatus. The display apparatus can include a transparent substrate having a viewing side and a second side opposite the viewing side. The display apparatus can include a light-absorbing conductive layer positioned on the second side of the transparent substrate. The display apparatus can include a low-temperature polycrystalline silicon (LTPS) transistor channel on a side of the light-absorbing conductive layer farthest from the transparent substrate such that a portion of the light-absorbing conductive layer optically obstructs the LTPS transistor channel from the viewing side of the transparent substrate. The display apparatus can include a light-absorbing dielectric layer coupled to the transparent substrate on a side of the LTPS transistor channel opposite the light-absorbing conductive layer. In some implementations, a footprint of a portion of the light-absorbing conductive layer substantially coincides with a footprint of the LTPS transistor channel.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

FIG. 1A shows a schematic diagram of an example direct-view microelectromechanical systems (MEMS)-based display apparatus.

FIG. 1B shows a block diagram of an example host device.

FIGS. 2A and 2B show views of an example dual actuator shutter assembly.

FIG. 3 shows a cross-sectional view of an example backplane for a display device.

FIG. 4 shows a cross-sectional view of another example backplane for a display device.

FIG. 5A shows a flow chart of an example process for manufacturing a backplane for a display device.

FIG. 5B shows a flow chart of another example process for manufacturing a backplane for a display device.

FIGS. 6A-6L show cross-sectional views of stages of construction of an example backplane for a display device according to the manufacturing process shown in FIG. 5A.

FIGS. 7A-7G show cross-sectional views of stages of construction of another example backplane for a display device that can be manufactured according to the manufacturing process shown in FIG. 5B.

FIGS. 8A and 8B show system block diagrams of an example display device that includes a plurality of display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that is capable of displaying an image, whether in motion (such as video) or stationary (such as still images), and whether textual, graphical or pictorial. The concepts and examples provided in this disclosure may be applicable to a variety of displays, such as liquid crystal displays (LCDs), organic light-emitting diode (OLED) displays, field emission displays, and electromechanical systems (EMS) and microelectromechanical (MEMS)-based displays, in addition to displays incorporating features from one or more display technologies.

The described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, wearable devices, clocks, calculators, television monitors, flat panel displays, electronic reading devices (such as e-readers), computer monitors, auto displays (such as odometer and speedometer displays), cockpit controls or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, in addition to non-EMS applications), aesthetic structures (such as display of images on a piece of jewelry or clothing) and a variety of EMS devices.

The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

A display device can produce images by modulating light using an array of display elements. The array of display elements can include MEMS shutter-based light modulators controlled by circuits included within a backplane of the display device. The backplane can include transistors and interconnects that include reflective materials, such as metals and semiconductors. In some implementations, the display backplane can be on a front substrate of the display device such that the backplane faces the viewer of the display device. The reflective layers included in the backplane may therefore reflect ambient light incident on the front substrate of the display device, which can reduce image quality. The backplane can include one or more light-absorbing layers to prevent such reflections. However, the materials suitable for absorbing light may be limited in implementations in which the channels of the transistors include low-temperature polycrystalline silicon (LTPS).

LTPS transistor channels are typically fabricated using a laser annealing process, which may result in high temperatures. Light-absorbing materials deposited on the backplane prior to fabrication of the LTPS channels must therefore be able to withstand these high temperatures. As a result, many of the materials typically used to absorb light in display devices, such as light-absorbing polymer materials, may not be suitable for use as a light-absorbing layer deposited before the annealing of LTPS channels. Light-absorbing conductive materials, such as dark metals, may be better able to withstand high temperatures, but the presence of expansive conductive layers within the backplane can introduce high levels of capacitance that undesirably increase the power required to drive the display elements.

Ambient light reflection can be reduced without unduly increasing capacitance by incorporating both conductive and non-conductive light-absorbing materials into a display backplane. For example, a light-absorbing conductive material that can withstand the temperatures generated by laser annealing can be deposited and patterned such that its footprint substantially coincides with the footprints of the LTPS channels to be fabricated in a subsequent step of the manufacturing process. In general, the footprint of a material, layer, or component of a display device can refer to the size and position of its two-dimensional projection normal to a surface of the display device. When the footprint of the light-absorbing conductive material at least matches, or extends beyond the footprint of the LTPS channels, the light-absorbing conductive material can optically obstruct light, such as incident or ambient light. In general, a component can be optically obstructed when it is not visible from the viewing side of the display device. Thus, when the light-absorbing conductive material is positioned closer to a viewing side of the display device than the LTPS transistor, the light-absorbing conductive material can optically obstruct the LTPS transistor. After the LTPS channels are fabricated using a laser annealing process, a light-absorbing dielectric material can be deposited and patterned such that it has broad coverage, with its footprint extending at least below the footprints of other reflective components of the backplane to be positioned above the light-absorbing dielectric material and removed at apertures defining an optical path through the display device. In some implementations, the footprint of the light-absorbing conductive material also can overlap with at least a portion of the footprint of the light-absorbing dielectric material. Together, the light-absorbing conductive material and the light-absorbing dielectric material can obstruct substantially all of the reflective surfaces within the backplane, thereby reducing reflection of ambient light by the backplane.

In some implementations, the light-absorbing dielectric material can be positioned beneath a metal layer that includes source-drain terminals of the transistors. This can allow the light-absorbing dielectric material to absorb ambient light that otherwise would reflect off of the source-drain terminals and any interconnects included in the same metal layer, which in turn allows for a the light-absorbing conductive material to have a smaller footprint within the backplane. For example, in some implementations the light-absorbing conductive material may have a footprint that substantially coincides with the footprints of the LTPS channels of the transistors in the backplane. Overall capacitance is therefore reduced. In some other implementations, the light-absorbing dielectric material can be positioned above the metal layer that includes source-drain terminals of the LTPS transistors. In such implementations, the footprint of the light-absorbing conductive layer can be expanded to substantially coincide with the footprints of the LTPS channels as well as the footprints of the source-drain terminals of the transistors and any other interconnects that may be optically unobstructed by the light-absorbing dielectric material.

Particular implementations of the subject matter described in this disclosure can be implemented to realize one or more of the following potential advantages. Incorporating both conductive and non-conductive light-absorbing materials into a display backplane can help to reduce reflection of ambient light. As discussed above, a display backplane may include reflective components, such as transistors and interconnects. When the display backplane is positioned on a substrate that faces the viewer of the display device, the reflective components may reflect ambient light that can reduce the quality of images produced by the display device. In addition, transistor channels tend to be photosensitive. Accordingly, in the aforementioned backplane architectures ambient light also can reduce the reliability of the switching of the transistors. Conductive and dielectric light-absorbing materials can be positioned within the backplane to optically obstruct transistor channels and other reflective components of the backplane, such that the light-absorbing materials are able to absorb ambient light that otherwise would be reflected back towards the viewer or that would impact transistor operation.

A light-absorbing layer of conductive material having a footprint coinciding with the footprints of the channels of the transistors in the backplane can allow for the use of laser annealing to fabricate the channels without damaging the light-absorbing layer. Laser annealing can result in relatively high temperatures that can degrade light-absorbing dielectric materials typically used to prevent ambient light from reflecting off of the LTPS channels. In contrast, many light-absorbing conductive materials, such as dark metals and alloys, can withstand the temperatures of laser annealing, and therefore can be positioned in close proximity to LTPS channels that are subjected to laser annealing, without significant risk of damage to the light-blocking conductive materials.

Positioning the light-absorbing conductive layer to obstruct a portion of the reflective components from ambient light and incorporating a light-absorbing dielectric material into a display backplane to optically obstruct a remainder of the reflective components from ambient light can reduce the overall capacitance of the display backplane without sacrificing the antireflective properties of the backplane. For example, while a light-absorbing dielectric material may be damaged if it is deposited before the LTPS channels are subjected to a laser annealing process, the light-absorbing dielectric material may be safely deposited after the laser annealing process is complete and the backplane has been allowed to cool. The light-absorbing dielectric material can be deposited prior to the deposition and patterning of one or more metal layers that include source-drain terminals, interconnects, and other reflective components of the backplane. Because the light-absorbing dielectric material is deposited beneath these reflective components, the light-absorbing dielectric material can absorb ambient light that otherwise would be reflected by these reflective components. The use of a light-absorbing dielectric material to obstruct a portion of the reflective components of the display also does not introduce additional capacitance into the backplane, and allows any conductive materials used to obstruct other reflective components to have a smaller footprint.

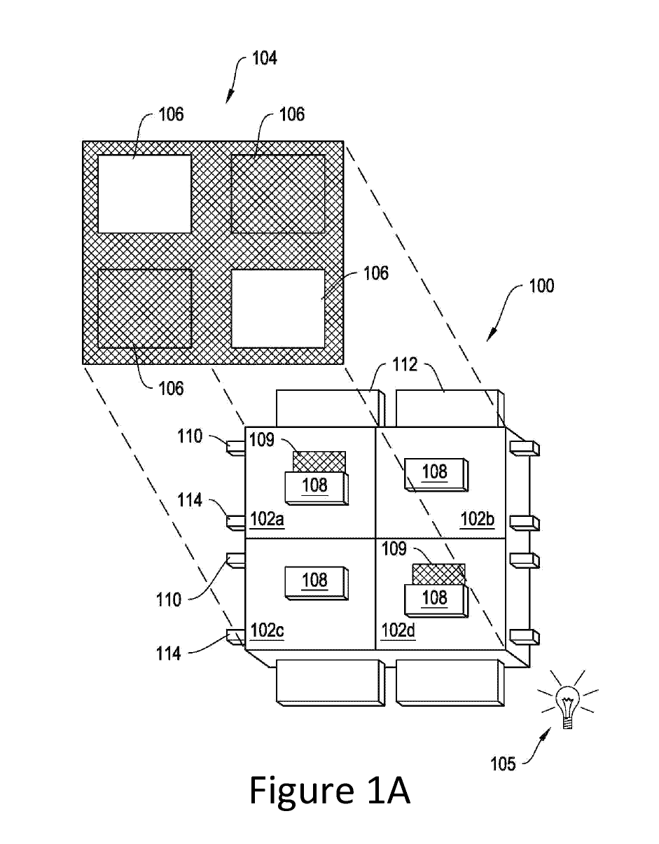

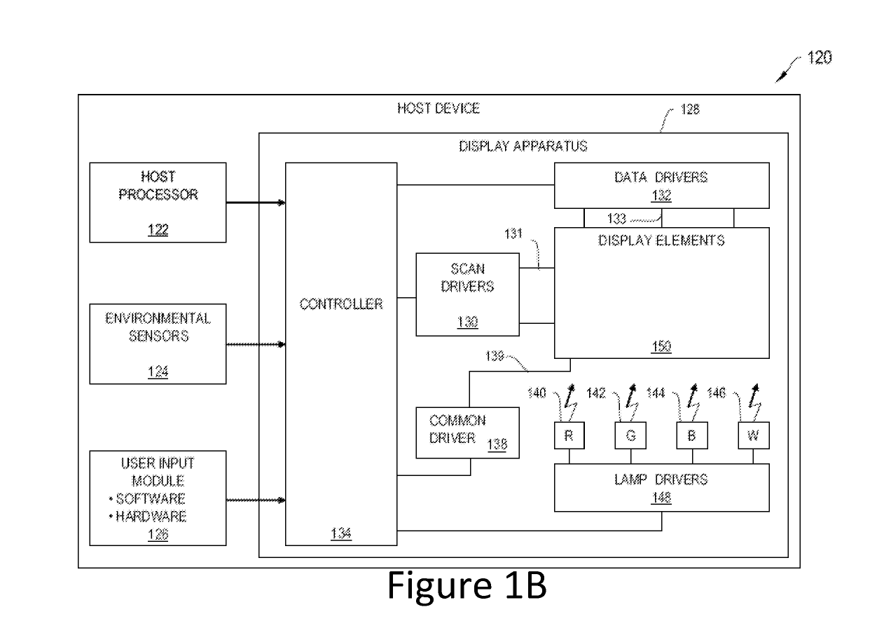

FIG. 1A shows a schematic diagram of an example direct-view MEMS-based display apparatus 100. The display apparatus 100 includes a plurality of light modulators 102a-102d (generally light modulators 102) arranged in rows and columns. In the display apparatus 100, the light modulators 102a and 102d are in the open state, allowing light to pass. The light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps positioned in the front of the display, i.e., by use of a front light.

In some implementations, each light modulator 102 corresponds to a pixel 106 in the image 104. In some other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide a luminance level in an image 104. With respect to an image, a pixel corresponds to the smallest picture element defined by the resolution of image. With respect to structural components of the display apparatus 100, the term pixel refers to the combined mechanical and electrical components utilized to modulate the light that forms a single pixel of the image.

The display apparatus 100 is a direct-view display in that it may not include imaging optics typically found in projection applications. In a projection display, the image formed on the surface of the display apparatus is projected onto a screen or onto a wall. The display apparatus is substantially smaller than the projected image. In a direct view display, the image can be seen by looking directly at the display apparatus, which contains the light modulators and optionally a backlight or front light for enhancing brightness of the display, the contrast of the display, or both.

Direct-view displays may operate in either a transmissive or reflective mode. In a transmissive display, the light modulators filter or selectively block light which originates from a lamp or lamps positioned behind the display. The light from the lamps is optionally injected into a lightguide or backlight so that each pixel can be uniformly illuminated. Transmissive direct-view displays are often built onto transparent substrates to facilitate a sandwich assembly arrangement where one substrate, containing the light modulators, is positioned over the backlight. In some implementations, the transparent substrate can be a glass substrate (sometimes referred to as a glass plate or panel), or a plastic substrate. The glass substrate may be or include, for example, a borosilicate glass, wine glass, fused silica, a soda lime glass, quartz, artificial quartz, Pyrex, or other suitable glass material.

Each light modulator 102 can include a shutter 108 and an aperture 109. To illuminate a pixel 106 in the image 104, the shutter 108 is positioned such that it allows light to pass through the aperture 109. To keep a pixel 106 unlit, the shutter 108 is positioned such that it obstructs the passage of light through the aperture 109. The aperture 109 is defined by an opening patterned through a reflective or light-absorbing material in each light modulator 102.

The display apparatus also includes a control matrix coupled to the substrate and to the light modulators for controlling the movement of the shutters. The control matrix includes a series of electrical interconnects (such as interconnects 110, 112 and 114), including at least one write-enable interconnect 110 (also referred to as a scan line interconnect) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the write-enabling voltage, V_{WE}), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In some other implementations, the data voltage pulses control switches, such as transistors or other non-linear circuit elements that control the application of separate drive voltages, which are typically higher in magnitude than the data voltages, to the light modulators 102. The application of these drive voltages results in the electrostatic driven movement of the shutters 108.

The control matrix also may include, without limitation, circuitry, such as a transistor and a capacitor associated with each shutter assembly. In some implementations, the gate of each transistor can be electrically connected to a scan line interconnect. In some implementations, the source of each transistor can be electrically connected to a corresponding data interconnect. In some implementations, the drain of each transistor may be electrically connected in parallel to an electrode of a corresponding capacitor and to an electrode of a corresponding actuator. In some implementations, the other electrode of the capacitor and the actuator associated with each shutter assembly may be connected to a common or ground potential. In some other implementations, the transistor can be replaced with a semiconducting diode, or a metal-insulator-metal switching element.

FIG. 1B shows a block diagram of an example host device 120 (i.e., cell phone, smart phone, PDA, MP3 player, tablet, e-reader, netbook, notebook, watch, wearable device, laptop, television, or other electronic device). The host device 120 includes a display apparatus 128 (such as the display apparatus 100 shown in FIG. 1A), a host processor 122, environmental sensors 124, a user input module 126, and a power source.

The display apparatus 128 includes a plurality of scan drivers 130 (also referred to as write enabling voltage sources), a plurality of data drivers 132 (also referred to as data voltage sources), a controller 134, common drivers 138, lamps 140-146, lamp drivers 148 and an array of display elements 150, such as the light modulators 102 shown in FIG. 1A. The scan drivers 130 apply write enabling voltages to scan line interconnects 131. The data drivers 132 apply data voltages to the data interconnects 133.

In some implementations of the display apparatus, the data drivers 132 are capable of providing analog data voltages to the array of display elements 150, especially where the luminance level of the image is to be derived in analog fashion. In analog operation, the display elements are designed such that when a range of intermediate voltages is applied through the data interconnects 133, there results a range of intermediate illumination states or luminance levels in the resulting image. In some other implementations, the data drivers 132 are capable of applying a reduced set, such as 2, 3 or 4, of digital voltage levels to the data interconnects 133. In implementations in which the display elements are shutter-based light modulators, such as the light modulators 102 shown in FIG. 1A, these voltage levels are designed to set, in digital fashion, an open state, a closed state, or other discrete state to each of the shutters 108. In some implementations, the drivers are capable of switching between analog and digital modes.

The scan drivers 130 and the data drivers 132 are connected to a digital controller circuit 134 (also referred to as the controller 134). The controller 134 sends data to the data drivers 132 in a mostly serial fashion, organized in sequences, which in some implementations may be predetermined, grouped by rows and by image frames. The data drivers 132 can include series-to-parallel data converters, level-shifting, and for some applications digital-to-analog voltage converters.

The display apparatus optionally includes a set of common drivers 138, also referred to as common voltage sources. In some implementations, the common drivers 138 provide a DC common potential to all display elements within the array 150 of display elements, for instance by supplying voltage to a series of common interconnects 139. In some other implementations, the common drivers 138, following commands from the controller 134, issue voltage pulses or signals to the array of display elements 150, for instance global actuation pulses which are capable of driving or initiating simultaneous actuation of all display elements in multiple rows and columns of the array.

Each of the drivers (such as scan drivers 130, data drivers 132 and common drivers 138) for different display functions can be time-synchronized by the controller 134. Timing commands from the controller 134 coordinate the illumination of red, green, blue and white lamps (140, 142, 144 and 146 respectively) via lamp drivers 148, the write-enabling and sequencing of specific rows within the array of display elements 150, the output of voltages from the data drivers 132, and the output of voltages that provide for display element actuation. In some implementations, the lamps are light emitting diodes (LEDs).

The controller 134 determines the sequencing or addressing scheme by which each of the display elements can be re-set to the illumination levels appropriate to a new image 104. New images 104 can be set at periodic intervals. For instance, for video displays, color images or frames of video are refreshed at frequencies ranging from 10 to 300 Hertz (Hz). In some implementations, the setting of an image frame to the array of display elements 150 is synchronized with the illumination of the lamps 140, 142, 144 and 146 such that alternate image frames are illuminated with an alternating series of colors, such as red, green, blue and white. The image frames for each respective color are referred to as color subframes. In this method, referred to as the field sequential color method, if the color subframes are alternated at frequencies in excess of 20 Hz, the human visual system (HVS) will average the alternating frame images into the perception of an image having a broad and continuous range of colors. In some other implementations, the lamps can employ primary colors other than red, green, blue and white. In some implementations, fewer than four, or more than four lamps with primary colors can be employed in the display apparatus 128.

In some implementations, where the display apparatus 128 is designed for the digital switching of shutters, such as the shutters 108 shown in FIG. 1A, between open and closed states, the controller 134 forms an image by the method of time division gray scale. In some other implementations, the display apparatus 128 can provide gray scale through the use of multiple display elements per pixel.

In some implementations, the data for an image state is loaded by the controller 134 to the array of display elements 150 by a sequential addressing of individual rows, also referred to as scan lines. For each row or scan line in the sequence, the scan driver 130 applies a write-enable voltage to the write enable interconnect 131 for that row of the array of display elements 150, and subsequently the data driver 132 supplies data voltages, corresponding to desired shutter states, for each column in the selected row of the array. This addressing process can repeat until data has been loaded for all rows in the array of display elements 150. In some implementations, the sequence of selected rows for data loading is linear, proceeding from top to bottom in the array of display elements 150. In some other implementations, the sequence of selected rows is pseudo-randomized, in order to mitigate potential visual artifacts. And in some other implementations, the sequencing is organized by blocks, where, for a block, the data for a certain fraction of the image is loaded to the array of display elements 150. For example, the sequence can be implemented to address every fifth row of the array of the display elements 150 in sequence.

In some implementations, the addressing process for loading image data to the array of display elements 150 is separated in time from the process of actuating the display elements. In such an implementation, the array of display elements 150 may include data memory elements for each display element, and the control matrix may include a global actuation interconnect for carrying trigger signals, from the common driver 138, to initiate simultaneous actuation of the display elements according to data stored in the memory elements.

In some implementations, the array of display elements 150 and the control matrix that controls the display elements may be arranged in configurations other than rectangular rows and columns. For example, the display elements can be arranged in hexagonal arrays or curvilinear rows and columns.

The host processor 122 generally controls the operations of the host device 120. For example, the host processor 122 may be a general or special purpose processor for controlling a portable electronic device. With respect to the display apparatus 128, included within the host device 120, the host processor 122 outputs image data as well as additional data about the host device 120. Such information may include data from environmental sensors 124, such as ambient light or temperature; information about the host device 120, including, for example, an operating mode of the host or the amount of power remaining in the host device's power source; information about the content of the image data; information about the type of image data; instructions for the display apparatus 128 for use in selecting an imaging mode; or any combination of these types of information.

In some implementations, the user input module 126 enables the conveyance of personal preferences of a user to the controller 134, either directly, or via the host processor 122. In some implementations, the user input module 126 is controlled by software in which a user inputs personal preferences, for example, color, contrast, power, brightness, content, and other display settings and parameters preferences. In some other implementations, the user input module 126 is controlled by hardware in which a user inputs personal preferences. In some implementations, the user may input these preferences via voice commands, one or more buttons, switches or dials, or with touch-capability. The plurality of data inputs to the controller 134 direct the controller to provide data to the various drivers 130, 132, 138 and 148 which correspond to optimal imaging characteristics.

The environmental sensor module 124 also can be included as part of the host device 120. The environmental sensor module 124 can be capable of receiving data about the ambient environment, such as temperature and or ambient lighting conditions. The sensor module 124 can be programmed, for example, to distinguish whether the device is operating in an indoor or office environment versus an outdoor environment in bright daylight versus an outdoor environment at nighttime. The sensor module 124 communicates this information to the display controller 134, so that the controller 134 can optimize the viewing conditions in response to the ambient environment.

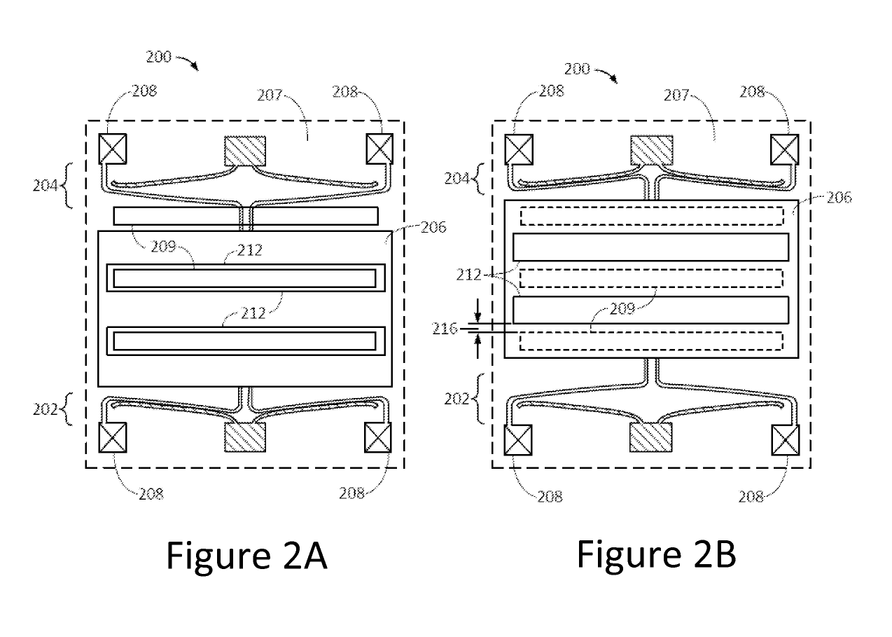

FIGS. 2A and 2B show views of an example dual actuator shutter assembly 200. The dual actuator shutter assembly 200, as depicted in FIG. 2A, is in an open state. FIG. 2B shows the dual actuator shutter assembly 200 in a closed state. The shutter assembly 200 includes actuators 202 and 204 on either side of a shutter 206. Each actuator 202 and 204 is independently controlled. A first actuator, a shutter-open actuator 202, serves to open the shutter 206. A second opposing actuator, the shutter-close actuator 204, serves to close the shutter 206. Each of the actuators 202 and 204 can be implemented as compliant beam electrode actuators. The actuators 202 and 204 open and close the shutter 206 by driving the shutter 206 substantially in a plane parallel to an aperture layer 207 over which the shutter is suspended. The shutter 206 is suspended a short distance over the aperture layer 207 by anchors 208 attached to the actuators 202 and 204. Having the actuators 202 and 204 attach to opposing ends of the shutter 206 along its axis of movement reduces out of plane motion of the shutter 206 and confines the motion substantially to a plane parallel to the substrate (not depicted).

In the depicted implementation, the shutter 206 includes two shutter apertures 212 through which light can pass. The aperture layer 207 includes a set of three apertures 209. In FIG. 2A, the shutter assembly 200 is in the open state and, as such, the shutter-open actuator 202 has been actuated, the shutter-close actuator 204 is in its relaxed position, and the centerlines of the shutter apertures 212 coincide with the centerlines of two of the aperture layer apertures 209. In FIG. 2B, the shutter assembly 200 has been moved to the closed state and, as such, the shutter-open actuator 202 is in its relaxed position, the shutter-close actuator 204 has been actuated, and the light blocking portions of the shutter 206 are now in position to block transmission of light through the apertures 209 (depicted as dotted lines).

Each aperture has at least one edge around its periphery. For example, the rectangular apertures 209 have four edges. In some implementations, in which circular, elliptical, oval, or other curved apertures are formed in the aperture layer 207, each aperture may have a single edge. In some other implementations, the apertures need not be separated or disjointed in the mathematical sense, but instead can be connected. That is to say, while portions or shaped sections of the aperture may maintain a correspondence to each shutter, several of these sections may be connected such that a single continuous perimeter of the aperture is shared by multiple shutters.

In order to allow light with a variety of exit angles to pass through the apertures 212 and 209 in the open state, the width or size of the shutter apertures 212 can be designed to be larger than a corresponding width or size of apertures 209 in the aperture layer 207. In order to effectively block light from escaping in the closed state, the light blocking portions of the shutter 206 can be designed to overlap the edges of the apertures 209. FIG. 2B shows an overlap 216, which in some implementations can be predefined, between the edge of light blocking portions in the shutter 206 and one edge of the aperture 209 formed in the aperture layer 207.

The electrostatic actuators 202 and 204 are designed so that their voltage-displacement behavior provides a bi-stable characteristic to the shutter assembly 200. For each of the shutter-open and shutter-close actuators, there exists a range of voltages below the actuation voltage, which if applied while that actuator is in the closed state (with the shutter being either open or closed), will hold the actuator closed and the shutter in position, even after a drive voltage is applied to the opposing actuator. The minimum voltage needed to maintain a shutter's position against such an opposing force is referred to as a maintenance voltage Vₘ.

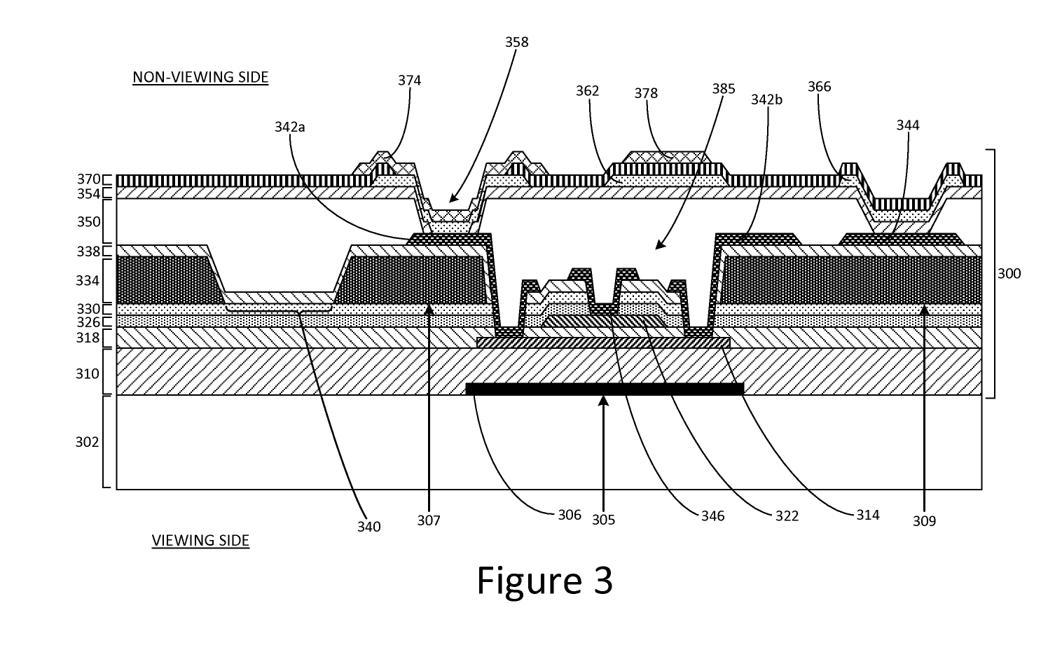

FIG. 3 shows a cross-sectional view of an example backplane 300 for a display device. The backplane 300 is positioned on a non-viewing side of a front substrate 302 (i.e., on a side of the front substrate 302 facing away from the viewing side of the display device), which may include materials such as glass or a transparent polymer. The backplane 300 includes several layers of materials patterned to define circuitry for driving display elements and to improve the quality of images produced by a display device including the backplane 300. For example, the backplane 300 includes a light-absorbing conductive layer 306 separated from a transistor channel 314 by a dielectric layer 310. The channel 314 is in contact with two source-drain terminals 342a and 342b (generally referred to as source-drain terminals 342), and is separated from a gate metal layer 322 by a dielectric layer 318. A gate terminal 346 contacts the gate metal layer 322. Together, the channel 314, the source-drain terminals 342, the gate metal layer 322, and the gate terminal 346 constitute a transistor 385. The backplane 300 also includes transparent dielectric layers 326 and 330 deposited over the gate metal layer 322, a light-absorbing dielectric layer 334 deposited over the dielectric layer 330, a passivation layer 338 deposited over the light-absorbing dielectric layer 334, and a planarizing layer 350 deposited over the passivation layer 338. The light-absorbing dielectric layer 334 defines an aperture 340. In some implementations, a light modulator (not shown in FIG. 3) can be configured to modulate light from a backlight positioned to the rear of the backplane 300 to contribute to the generation of an image.

An interconnect 344 included in the same layer as the source-drain terminals 342 and the gate terminal 346 is positioned above the passivation layer 338, and is separated from an interconnect 366 by a dielectric layer 354. An interconnect 362 and a first portion of a via 358 contacting the source-drain terminal 342a are included within the same metal layer as the interconnect 366. A layer of transparent conductive material 374 includes a second portion of the via 358, as well as an interconnect 378. The interconnect 378 is separated from the interconnect 362 by a dielectric layer 370.

In some implementations, components of the backplane 300 may be substantially reflective. For example, the source-drain terminals 342 and the interconnects 344, 362, and 366 can include reflective materials such as aluminum (Al), copper (Cu), silver (Ag), nickel (Ni), chromium (Cr), and titanium (Ti), among others. The channel 314 can include a reflective semiconducting material, such as low-temperature polycrystalline silicon (LTPS). Because the backplane 300 is positioned on the front substrate 302, these reflective components can reflect ambient light back towards a viewer of the display device. Such reflections can reduce image quality, for example by reducing the contrast ratio of the display device. Furthermore, some of the components of the backplane 300 may have electrical properties that are sensitive to light. For example, the channel 314 can include a semiconductor material whose operating characteristics are altered when the channel 314 is exposed to light. For example, some transistors may experience light induced current flow in the presence of ambient light, reducing the reliability of the transistors' switching operation. In order to prevent or substantially reduce ambient light reflection and the negative effects of ambient light on the reliability of the various components of the backplane 300, the light-absorbing conductive layer 306 and the light-absorbing dielectric layer 334 together are configured to obstruct ambient light directed towards the reflective components of the backplane 300.

FIG. 3 shows three illustrative light rays 305, 307, and 309, each representing ambient light directed approximately normal to the backplane 300. The light-absorbing conductive layer 306 is patterned to have a footprint that substantially coincides with a footprint of the channel 314. Therefore, ambient light that would otherwise reflect off of the channel 314 is instead absorbed by the light-absorbing conductive layer 306, as illustrated by the light ray 305. The light-absorbing dielectric layer 334 is patterned to have a footprint that substantially coincides with the footprints of other reflective components that are not obstructed by the light-absorbing conductive layer 306. For example, the light-absorbing dielectric layer 334 obstructs the source-drain terminals 342 and the interconnect 344, thereby preventing the light rays 307 and 309 from reflecting off of these reflective components.

As discussed above, the channel 314 can include LTPS. In some implementations, the use of underlying dielectric light-absorbing materials may not be compatible with the manufacturing processes used in fabricating LTPS channels, such as the channel 314. In particular, the annealing of an LTPS channel may irreparably damage the underlying light-absorbing material. For example, in some implementations, the channel 314 can be fabricated by first depositing an amorphous silicon (a-Si) layer, and then using a laser annealing process to convert the amorphous silicon layer into polycrystalline silicon. The converted polycrystalline silicon layer can then be patterned into a channel 314. While the term LTPS suggests low temperatures are used, it should be understood that the temperatures used in laser annealing are low relative to the temperatures required to produce polycrystalline silicon using traditional techniques, yet still may be sufficiently high to damage light-absorbing dielectric materials. In some implementations, light-absorbing dielectric materials may deform, combust, or generally react to the annealing process in a manner that may damage adjacent structures in the backplane 300.

Accordingly, to block ambient light that could reflect off of the channel 314, the backplane 300 includes the light-absorbing conductive layer 306, which can withstand the high temperatures generated by the laser annealing process applied to the channel 314. In some implementations, the light-absorbing conductive layer 306 can include a dark metal, such a molybdenum (Mo), or Mo alloys such as molybdenum-tungsten (MoW). In some implementations, other light-absorbing metals or alloys may be used, provided that they are able to withstand the temperatures generated by laser annealing of the channel 314.

While light-absorbing conductive materials are useful for their ability tolerate high temperatures, in some implementations such light-absorbing conductive materials may increase the overall capacitance of the backplane 300, which can lead to increased power consumption. Therefore, in some implementations, it may be desirable to select a relatively small footprint for the light-absorbing conductive layer 306 to avoid unduly increasing the capacitance of the backplane 300. For example, as shown in FIG. 3, the light-absorbing conductive layer 306 has a footprint that substantially coincides with, and does not extend substantially beyond, the footprint of the channel 314 of the transistor 385 (and the channels of other transistors that may be included within the backplane 300). In some implementations, the light-absorbing conductive layer 306 extends no more than a few microns horizontally beyond the footprint of the channel 314. This horizontal extension is generally less than 10 microns beyond the footprint of the channel, and in some implementations can be less than about 5 microns. In some other implementations, the footprint of the light-absorbing conductive layer 306 extends between about 1 micron and about 10 microns, or between about 3 microns and about 5 microns, beyond the footprint of the channel 314. Slightly or modestly extending the footprint of the light-absorbing conductive layer 306 beyond the exact footprint of the channel 314 can allow the light-absorbing conductive layer 306 to prevent off-angle ambient light from contacting the channel 314. In some implementations, the footprint of the light-absorbing conductive layer 306 can be constrained to substantially coincide with the channel 314 of the transistor 385 (and the channels of other transistors that may be included within the backplane 300). Other reflective components of the backplane 300, such as the source-drain terminals 342 and the interconnects 344 and 366, may not be substantially obstructed by the light-absorbing conductive layer 306. Instead, such reflective components can be obstructed by the light-absorbing dielectric layer 334.

In some implementations, the light-absorbing dielectric layer 334 can include a dark polymer material, such as a black resin or a polymer composite including carbon black. In some other implementations, the light-absorbing dielectric layer 334 can include dark spin-on-glass (DSOG) or carbon-doped silicates and siloxanes, such as hydrogen silsesquioxane (HSQ) and methylsilozane. The light-absorbing dielectric layer 334 can be deposited conformally or as a planarizing layer. In some implementations, temperatures high enough to damage the light-absorbing dielectric layer 334 are experienced during the laser annealing process used to fabricate the channel 314. Because the light-absorbing dielectric layer 334 is deposited after the annealing of the channel 314, the light-absorbing dielectric layer 334 is not exposed to the potentially damaging temperatures of the laser annealing process. Furthermore, the light-absorbing dielectric layer does not substantially increase the capacitance of the backplane 300, and therefore its footprint may be relatively expansive compared to the footprint of the light-absorbing conductive layer 306 without increasing capacitance of the backplane 300.

It should be understood that the arrangement of the light-absorbing conductive layer 306 and the light-absorbing dielectric layer 334 shown in FIG. 3 is illustrative only. In some implementations, the footprint of the light-absorbing conductive layer 306 is not limited solely to the footprint of the channel 314, and can be significantly larger than the footprint of the channel 314. For example, the footprint of the light-absorbing conductive layer 306 also may overlap the combined footprint of most or all of the reflective components of the backplane 300 not optically obstructed by the light-absorbing dielectric layer 334. In general, the light-absorbing dielectric layer 334 can have a footprint that obstructs a first portion of the reflective components of the backplane 300 and the light-absorbing conductive layer 306 can have a footprint that obstructs the remainder of the reflective components of the backplane 300 that are not obstructed by the light-absorbing dielectric layer 334. Some overlap between the footprint of the light-absorbing dielectric layer 334 and the footprint of the light-absorbing conductive layer 306 may be present in some implementations.

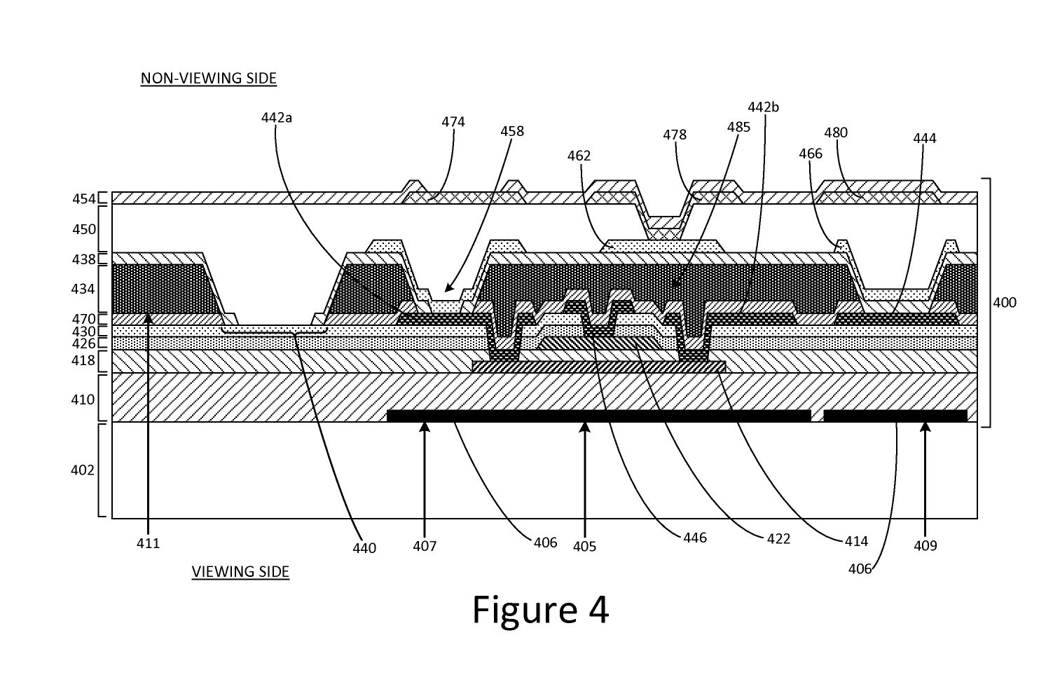

FIG. 4 shows a cross-sectional view of another example backplane 400 for a display device. The backplane 400 includes many features similar to those discussed above in connection with the backplane 300 shown in FIG. 3. For example, the backplane 400 is positioned over a front transparent substrate 402, which may be formed from, or may include, materials such as a transparent polymer or glass. The backplane 400 includes a light-absorbing conductive layer 406 separated from a channel 414 by a dielectric layer 410. The channel 414 is in contact with two source-drain terminals 442a and 442b (generally referred to as source-drain terminals 442), and is separated from a gate metal layer 422 by a dielectric layer 418. A gate terminal 446 contacts the gate metal layer 422. Together, the channel 414, the source-drain terminals 442, the gate metal layer 422, and the gate terminal 446 constitute a transistor 485. The backplane 400 also includes dielectric layers 426 and 430 and a passivation layer 470 deposited over the gate metal layer 422, a light-absorbing dielectric layer 434 deposited over the passivation layer 470, a passivation layer 438 deposited over the light-absorbing dielectric layer 434, and a planarizing layer 450 deposited over the passivation layer 438. The light-absorbing dielectric layer 434 defines an aperture 440. In some implementations, a light modulator (not shown in FIG. 4) can be configured to modulate light from a backlight positioned to the rear of the backplane 400 to contribute to the generation of an image.

An interconnect 444 is included in the same layer as the source-drain terminals 442 and the gate terminal 446, and is separated from an interconnect 466 by the passivation layer 438. The layer in which the interconnect 466 is included also includes an interconnect 462 and a via 458 contacting the source-drain terminal 442a. A layer of transparent conductive material includes an interconnect 474, a via 478 contacting the interconnect 462, and an interconnect 480. The layer of transparent conductive material is covered by a passivation layer 454.

One primary difference between the backplane 400 and the backplane 300 shown in FIG. 3 is that the light-absorbing dielectric layer 434 is positioned behind, rather than in front of, the metal layer that includes the source-drain terminals 442, the gate terminal 446, and the interconnect 444 with respect to the viewing side of the display device. As a result, the light-absorbing dielectric layer 434 is unable to obstruct ambient light directed towards these reflective components of the backplane 400. To account for this difference, the footprint of the light-absorbing conductive layer 406 is expanded to coincide with the footprint of substantially the entire transistor 485. That is, the footprint of the light-absorbing conductive layer 406 coincides with the footprints of both of the source-drain terminals 442 as well as the channel 414. The footprint of the light-absorbing conductive layer 406 also coincides with the footprint of the interconnect 444. Thus, the illustrative ambient light rays 405, 407, and 409 directed towards the channel 414, the source-drain terminal 442a, and the interconnect 409, respectively, are absorbed by the light-absorbing conductive layer 406. As with the backplane 300 shown in FIG. 3, the footprint of the light-absorbing conductive layer 406 can extend slightly beyond the footprint of the reflective materials it is optically obstructing in order to help absorb off-angle ambient light. For example, in some implementations, the footprint of the light-absorbing conductive layer 406 extends no more than a few microns horizontally beyond the footprint of the reflective components of the backplane 400 it is optically obstructing. This horizontal extension is generally less than 10 microns beyond the footprint of the channel, and in some implementations can be less than about 5 microns. In some other implementations, the footprint of the light-absorbing conductive layer 406 extends between about 1 micron and about 10 microns, or between about 3 microns and about 5 microns, beyond the footprint of the reflective components of the backplane 400 it is optically obstructing. In some implementations, the light-absorbing conductive layer 406 can be constrained to have a footprint that substantially coincides with the channel 414, the interconnect 444, and other reflective components that may be included within the backplane 400 that are not optically obstructed by the light-absorbing dielectric layer 434. The light-absorbing dielectric layer 434 can absorb ambient light that is not obstructed by the light-absorbing conductive layer 406, as illustrated by the ambient light ray 411.

In some implementations, the light-absorbing conductive layer 406 also can include the materials discussed above as suitable for the light-absorbing conductive layer 306 shown in FIG. 3. Similarly, the materials discussed above as suitable for the light-absorbing dielectric layer 334 shown in FIG. 3 also can be included in the light-absorbing dielectric layer 434.

It should be understood that the arrangement of the light-absorbing conductive layer 406 and the light-absorbing dielectric layer 434 shown in FIG. 4 is illustrative only. In some implementations, the footprint of the light-absorbing conductive layer 406 can be significantly larger than the footprint of the transistor 485. In general, the light-absorbing dielectric layer 434 can have a footprint that obstructs a first portion of the reflective components of the backplane 400 and the light-absorbing conductive layer 406 can have a footprint that obstructs the remainder of the reflective components of the backplane 400 that are not obstructed by the light-absorbing dielectric layer 434. Some overlap between the footprint of the light-absorbing dielectric layer 434 and the footprint of the light-absorbing conductive layer 406 may be present in some implementations.

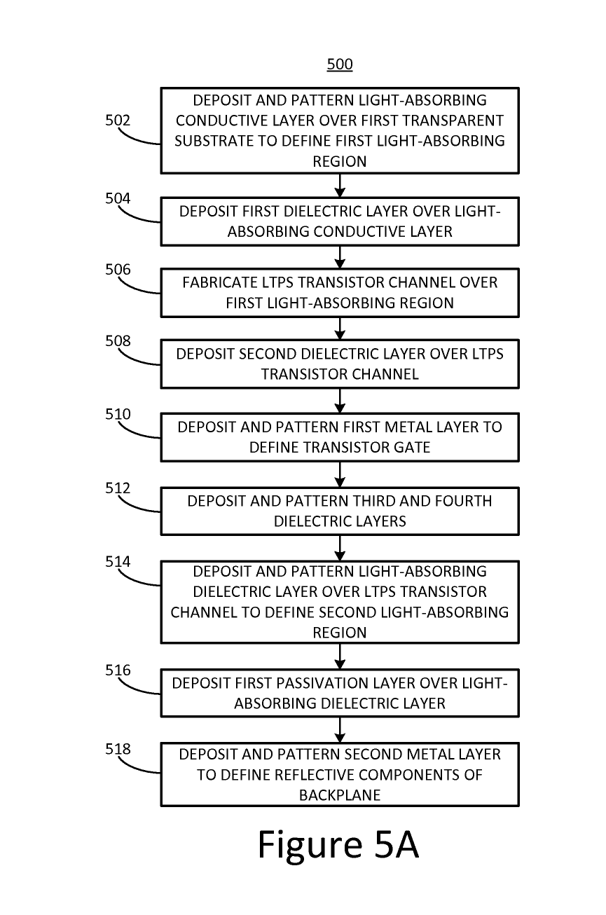

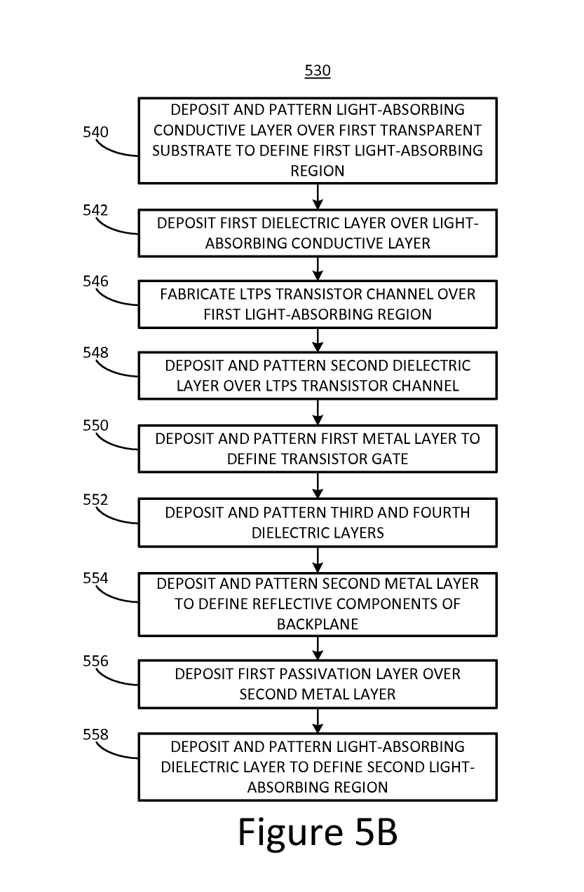

FIG. 5A shows a flow chart of an example process 500 for manufacturing a backplane for a display device. In brief overview, the process 500 includes depositing and patterning a light-absorbing conductive layer over a first transparent substrate to define a first light-absorbing region (stage 502), depositing a first dielectric layer over the light-absorbing conductive layer (stage 504), fabricating an LTPS transistor channel over the first light-absorbing region (stage 506), depositing a second dielectric layer over the LTPS transistor channel (stage 508), depositing and patterning a first metal layer to define a transistor gate (stage 510), depositing and patterning third and fourth dielectric layers (stage 512), depositing and patterning a light-absorbing dielectric layer over the LTPS transistor channel (stage 514), depositing a first passivation layer over the light-absorbing dielectric layer (stage 516), and depositing and patterning a second metal layer to define reflective components of the backplane (stage 518).

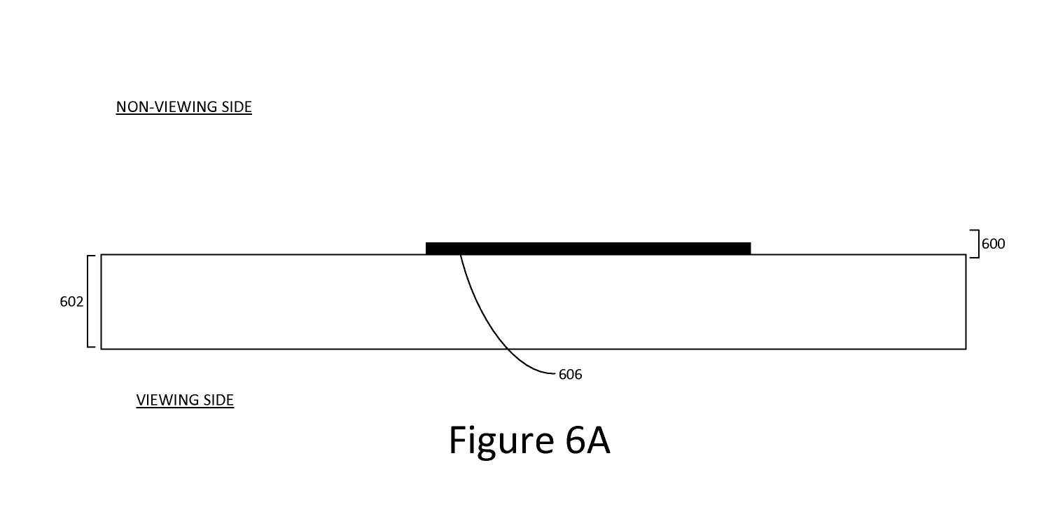

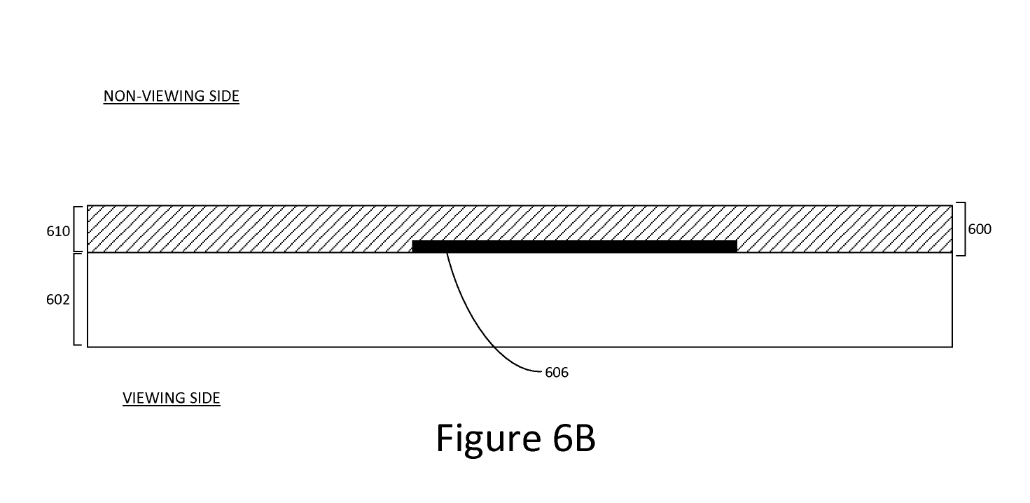

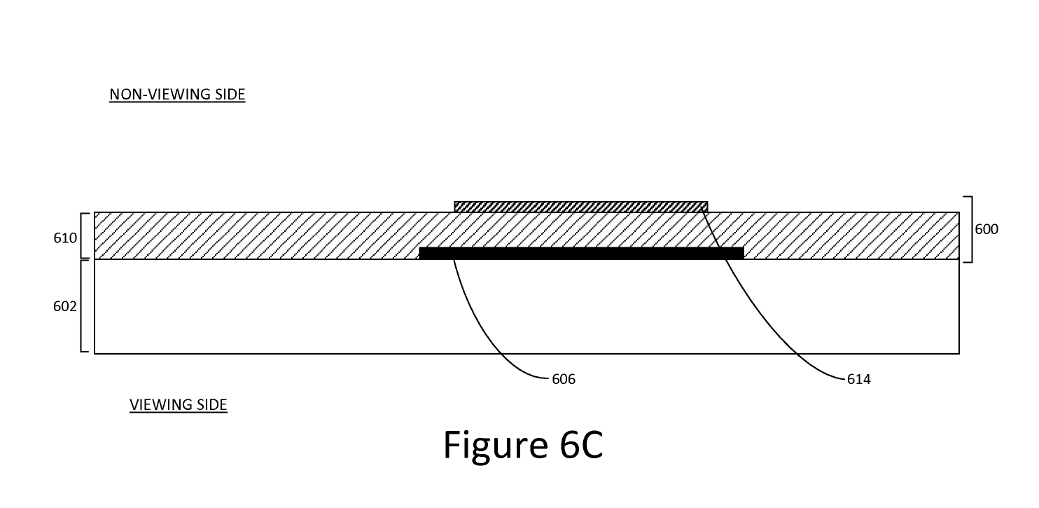

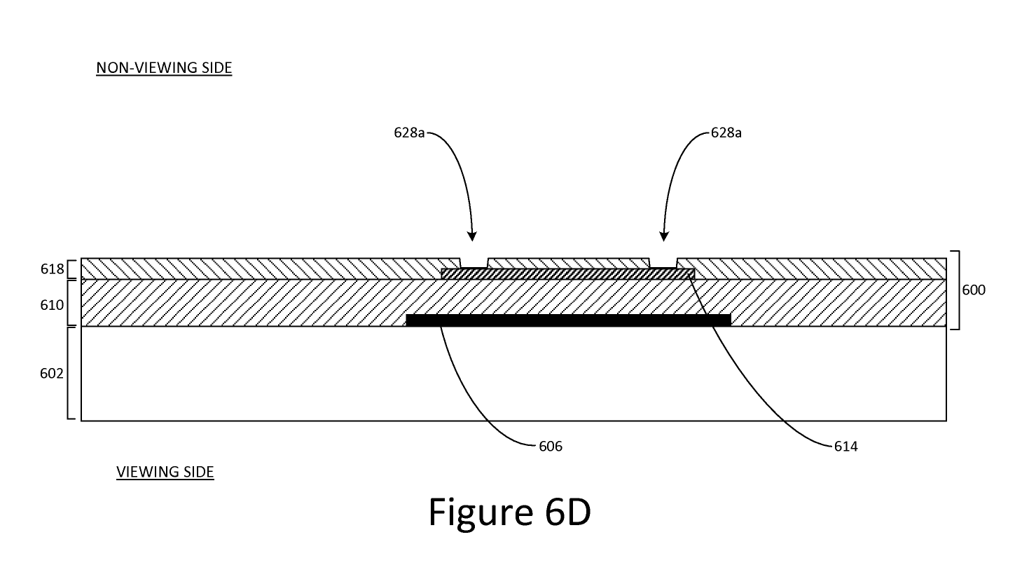

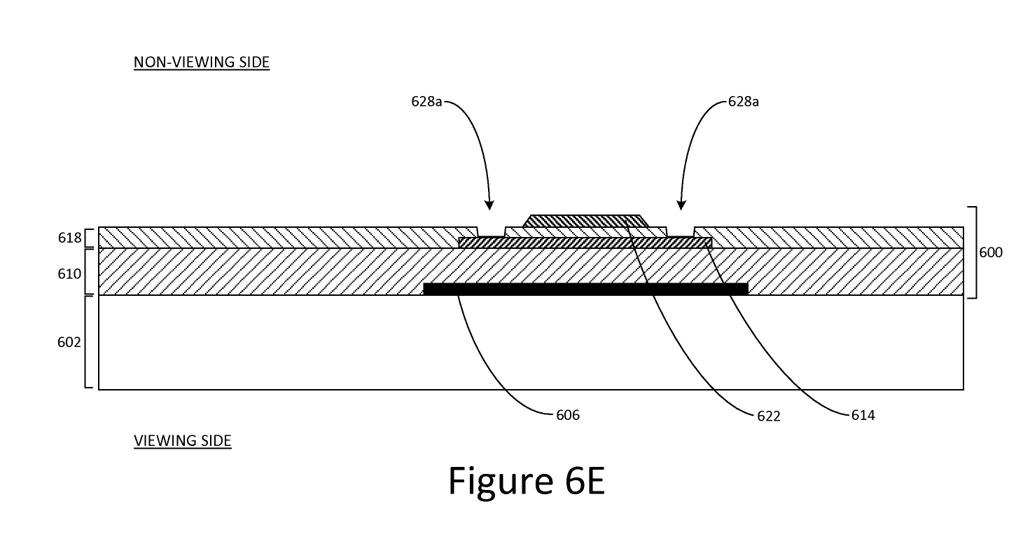

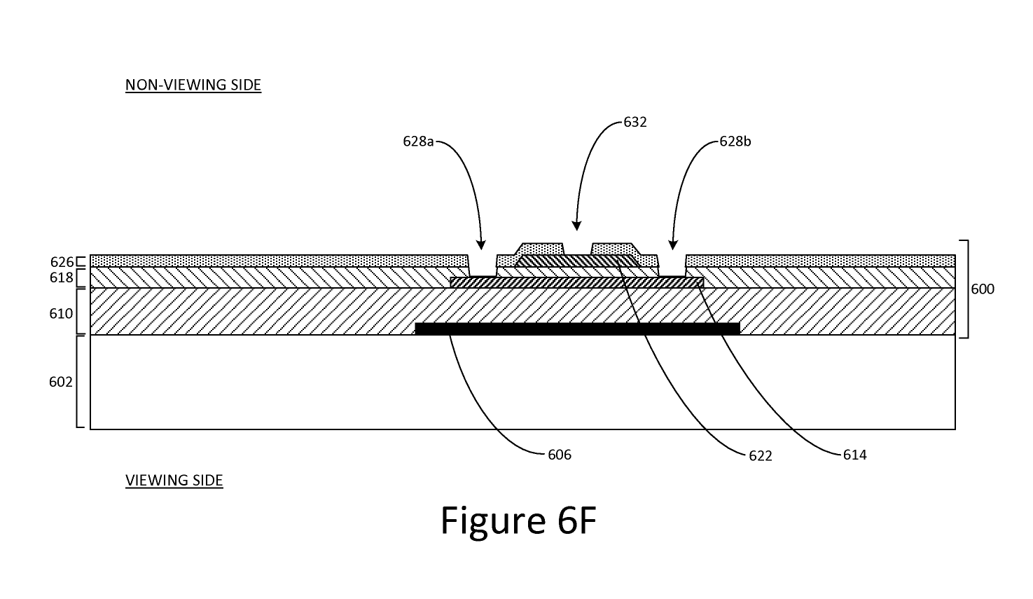

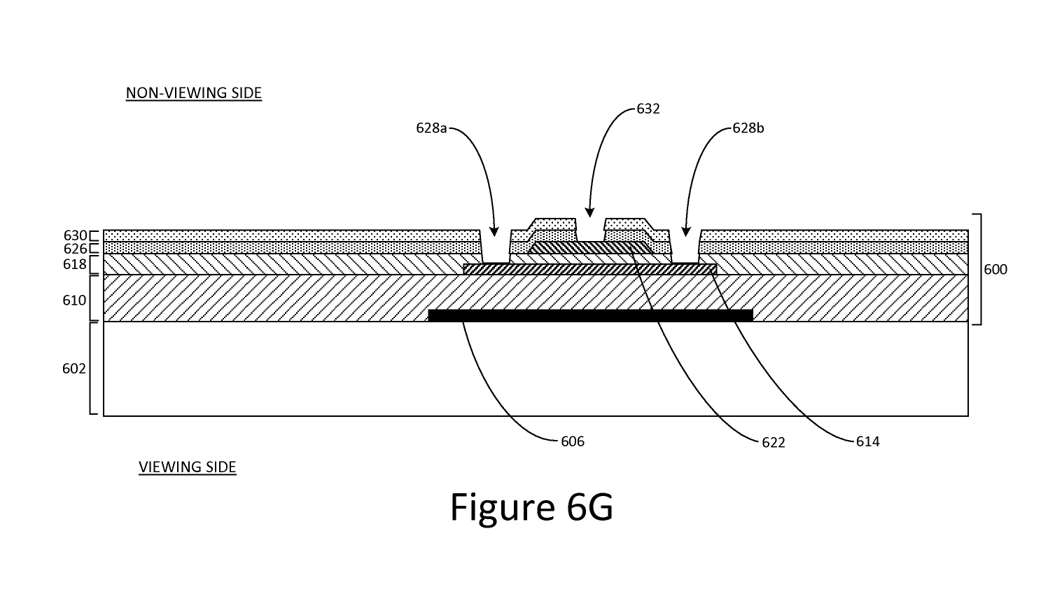

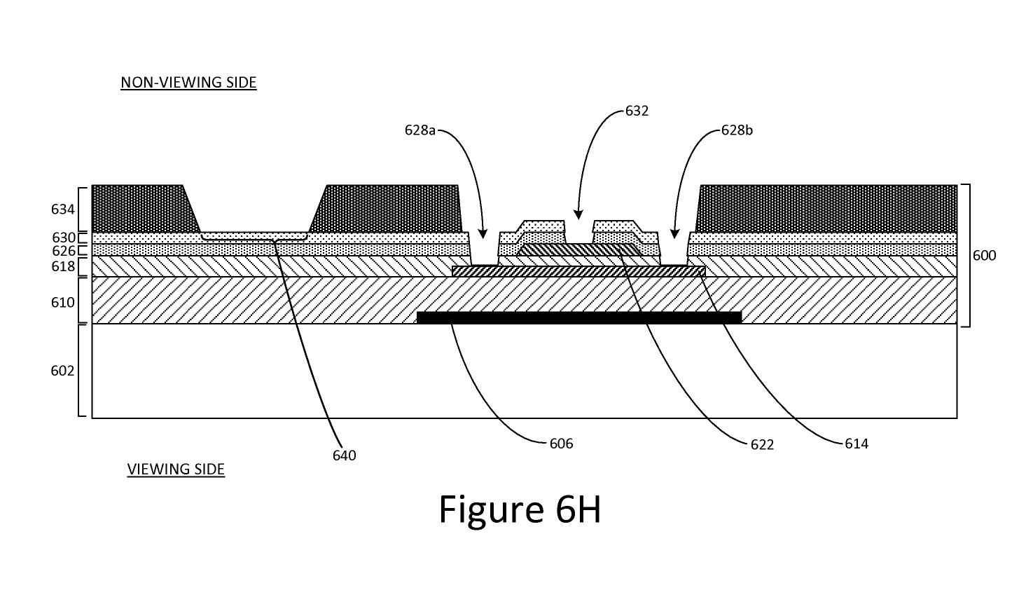

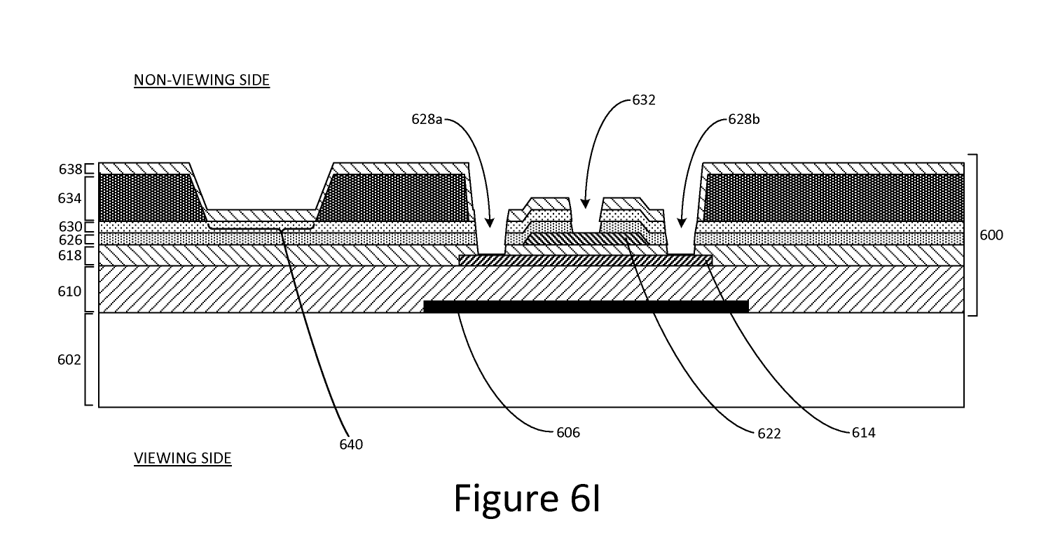

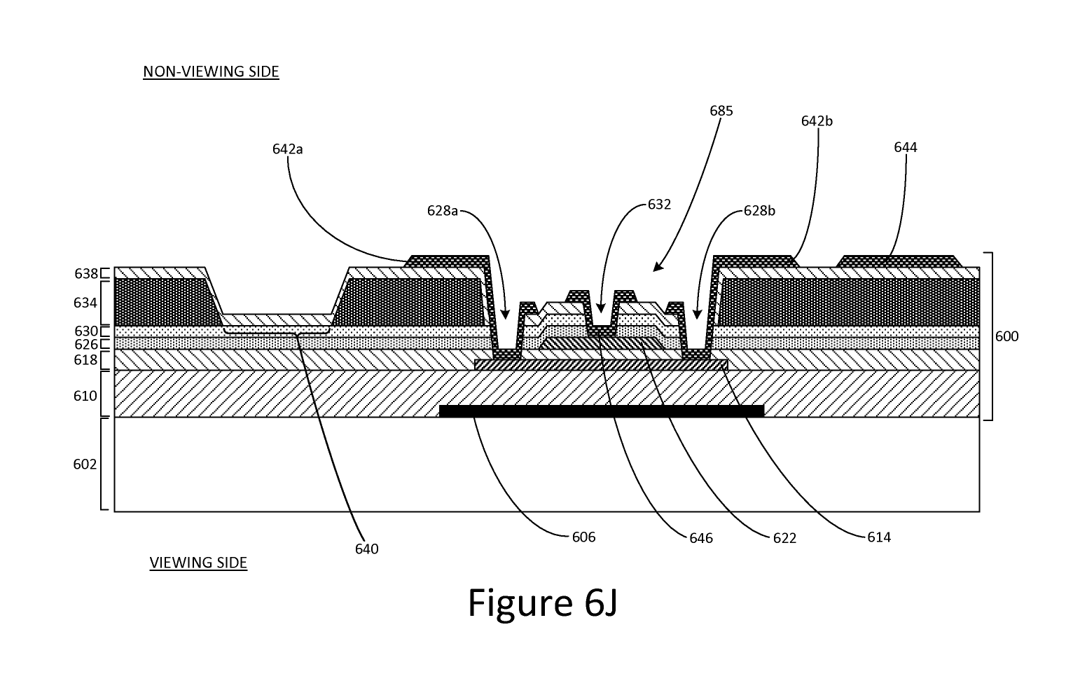

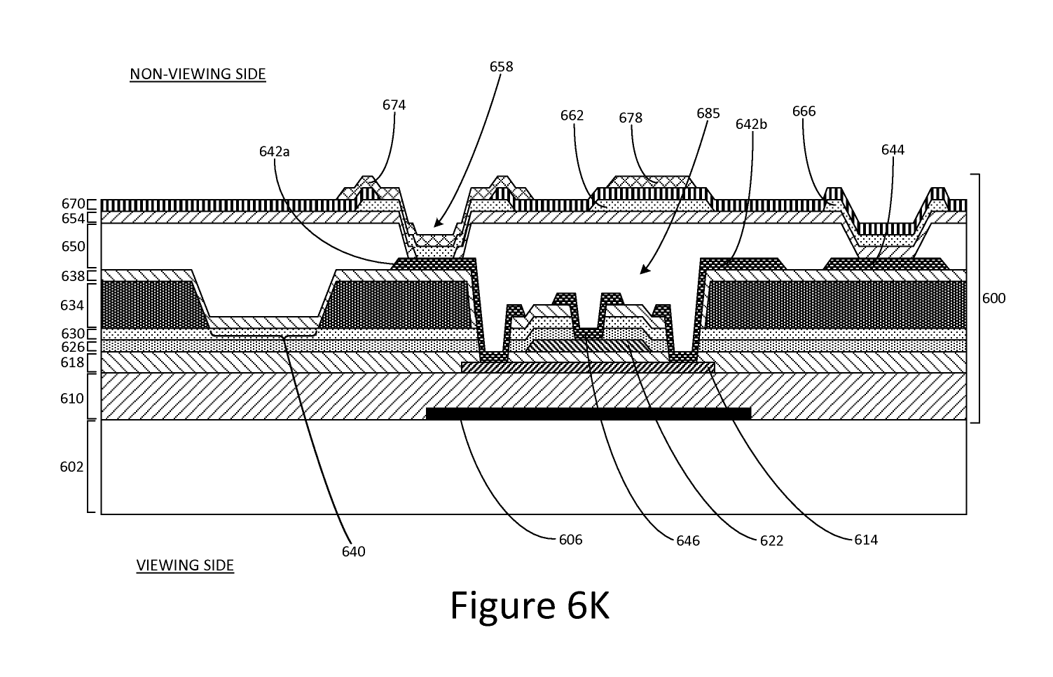

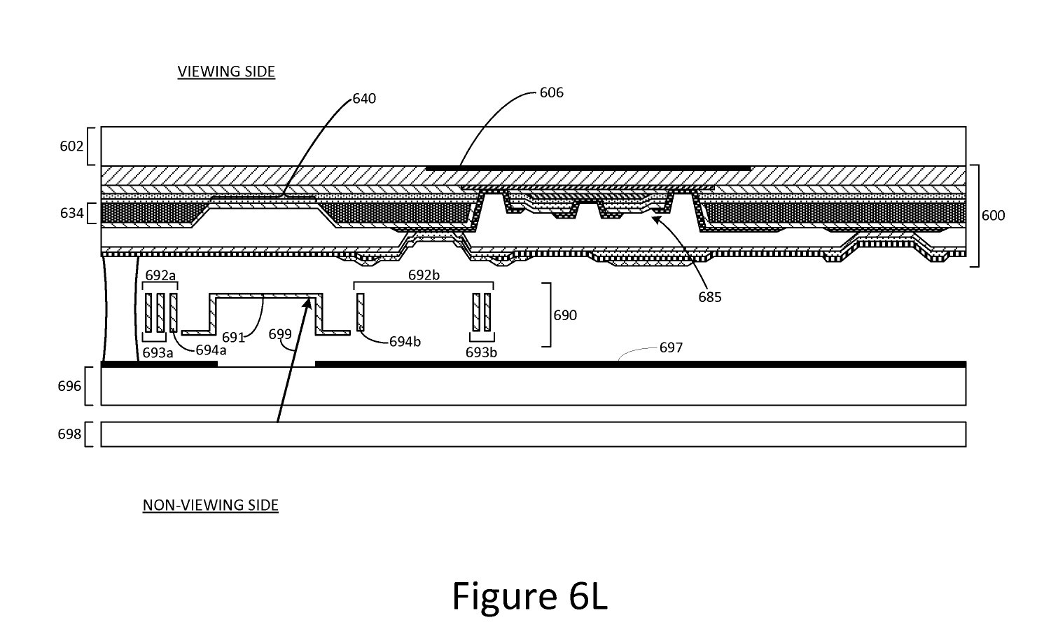

FIGS. 6A-6L show cross-sectional views of stages of construction of an example backplane 600 for a display device according to the manufacturing process 500 shown in FIG. 5A. The backplane 600 is similar to the backplane 300 shown in FIG. 3. The process 500 of FIG. 5A and the manufacturing stages of FIGS. 6A-6L are described together below.

The process 500 includes depositing and patterning a light-absorbing conductive layer over a first transparent substrate to define a first light-absorbing region (stage 502). As shown in FIG. 6A, the light-absorbing conductive layer 606 can be deposited and patterned over a substrate 602 positioned on the viewing side of the display device. In some implementations, the light-absorbing conductive layer 606 can include any conductor that is also substantially light-absorbing. For example, in some implementations, the light-absorbing conductive layer 606 can include a thin film of metal or an alloy including, but not limited to, Mo, Ti, tungsten (W), and tantalum (Ta). In some implementations, the light-absorbing conductive layer 606 can be deposited by sputter deposition in high gas pressures (such as sputtering atmospheres in excess of 20 mtorr). In some other implementations, a rough metal layer having light-absorbing properties can be fabricated by the liquid spray or plasma spray application of a dispersion of metal particles, followed by thermal sintering. The deposited light-absorbing conductive layer 606 can then be patterned to result in the first light-absorbing portion shown in FIG. 6A. In some other implementations, the light-absorbing conductive layer 606 can include a stack of multiple materials, including conductive materials and dielectrics, provided that the stack of materials is able to withstand the temperatures of the annealing process. In some implementations, the light-absorbing conductive layer can absorb at least about 50% of the light incident on its surface. That is, the reflectance of the light-absorbing conductive layer 606 can be less than about 50%. In some other implementations, the reflectance of the light-absorbing conductive layer 606 can be less than about 40%, less than about 25%, or less than about 15%. The light-absorbing conductive layer can be patterned to define a first light-absorbing region. In some implementations, the first light-absorbing region can have a footprint that substantially coincides with, and extends slightly beyond, one or more reflective components of the backplane 600 to be fabricated or deposited in subsequent steps. For example, as shown in FIGS. 6A-6L, the first light-absorbing region can have a footprint that substantially coincides with a channel of a transistor to be fabricated in a subsequent step.

A first dielectric layer 610 can be deposited over the light-absorbing conductive layer 606 (stage 504), as shown in FIG. 6B. The first dielectric layer 610 can include a material such as silicon dioxide (SiO₂), silicon nitride (Si₃N₄), aluminum oxide (Al₂O₃), titanium oxide (TiO₂), hafnium oxide (HfO₂), or tantalum pentoxide (Ta₂O₅). In some implementations, deposition techniques including, but not limited to, chemical vapor deposition (CVD), plasma enhanced chemical vapor deposition (PECVD), low pressure chemical vapor deposition (LPCVD), atomic or self-limited layer deposition (ALD), evaporation, etc., may be used to deposit the first dielectric layer 610.

An LTPS channel of a transistor can be fabricated over the first light-absorbing region (stage 506). The results of this stage are shown in FIG. 6C. The LTPS channel 614 can be deposited and patterned as amorphous silicon, and a laser annealing process can be applied to produce the LTPS channel 614. In some implementations, a layer of amorphous silicon can be deposited and then converted to polycrystalline silicon using laser annealing before being patterned into the LTPS channel 614. In some implementations, the laser annealing process may generate high temperatures that could damage traditional light-absorbing dielectric materials. However, because the light-absorbing conductive layer 606 is able to withstand high temperatures, the laser annealing process will not damage the underlying light-absorbing conductive layer 606.

The fabrication of the LTPS channel 614 can be followed by the deposition and patterning of a second dielectric layer 618 over the LTPS transistor channel 614 (stage 508). The results of this stage are shown in FIG. 6D. In some implementations, the second dielectric layer 618 can include materials similar to those included in the first dielectric layer 610. In some implementations, the material of the second dielectric layer 618 can be selected based on its adhesive properties with respect to polycrystalline silicon, to ensure that the second dielectric layer 618 will adhere to the LTPS channel 614. The second dielectric layer 618 can be patterned to define openings 628a and 628b which expose respective portions of the underlying LTPS channel 614. The openings 628a and 628b can provide openings through which source-drain terminals fabricated in a subsequent stage can contact the LTPS channel 614. In some implementations, the thickness of the second dielectric layer 618 can be based on a desired thickness of the gate dielectric of a transistor that will include the channel 614. The thickness of the gate dielectric can affect several electrical characteristics of the transistor, such as its transconductance, capacitance, and switching speed.

The process 500 includes depositing and patterning a first metal layer to define a transistor gate 622 (stage 510). FIG. 6E shows the results of this stage. The gate 622 can include conductive materials including, but not limited to, Al, Cu, Ag, Ni, Cr, Ti, etc. As the gate 622 is deposited after the deposition of the channel 614, the resulting transistor can be referred to as a top-gate transistor. In some other implementations, the gate 622 may be deposited and patterned before the fabrication of the channel 614, and the transistor may be referred to as a bottom-gate transistor.

Deposition and patterning of the gate 622 can be followed by the deposition and patterning of a third dielectric layer 626 and a fourth dielectric layer 630 (stage 512). As shown in FIG. 6F, the third dielectric layer 626 can include materials similar to those included in the first dielectric layer 610 and can be patterned to define openings that coincide with the openings 628a and 628b in the second dielectric layer 618, as well as an opening 632 above the gate 622 into which a gate terminal can be deposited in a subsequent step. The fourth dielectric layer 630 can be deposited over the third dielectric layer 626, and can be patterned to define openings coinciding with the openings 628a and 628b in the second dielectric layer 618, as well as the opening 632 in the third dielectric layer 626, as shown in FIG. 6G.

A light-absorbing dielectric layer 634 can be deposited and patterned over the LTPS transistor channel 614 to define a second light-absorbing region (stage 514). The results of this stage are shown in FIG. 6H. In some implementations, the light-absorbing dielectric layer 634 can include a light-absorbing polymer material or DSOG. The light-absorbing dielectric layer 634 can be deposited conformally or as a planarization layer. In some implementations, the second light-absorbing region can be selected to correspond to the position of reflective components of the backplane 600 that are not obstructed by the first light-absorbing region defined by the light-absorbing conductive layer 606. For example, the second light-absorbing region can correspond to portions of the source-drain terminals and an interconnect that are not obstructed by the first light-absorbing region. In some other implementations, the second light-absorbing region may partially overlap the first light-absorbing region defined by the light-absorbing conductive layer 606. The light-absorbing dielectric layer 634 also can be patterned to define an optical aperture 640.

A first passivation layer 638 can be deposited over the light-absorbing dielectric layer 634 (stage 516). The first passivation layer 638 can be patterned to have openings coinciding with the openings 628a and 628b in the second dielectric layer 618, as well as the opening 632 in the third dielectric layer 626. The first passivation layer can include any insulating material, such as SiO₂ or Si₃N₄. The results of this stage are shown in FIG. 6I.

A second reflective metal layer can be deposited and patterned to define reflective components of the backplane 600 (stage 518). The results of this stage are shown in FIG. 6J. In this example, reflective components of the control matrix include the source-drain terminals 642a and 642b of the transistor 685 and an interconnect 644. In some implementations, the reflective metal layer can include metals such as Al, Cu, Ag, Ni, Cr, W, and Ti. The reflective metal layer is deposited to fill the openings 628a and 628b in the second dielectric layer 618, as well as the opening 632 in the third dielectric layer 626. After the reflective metal layer is patterned, the source-drain terminals 642a and 642b contact the channel 614 and a gate terminal 646 contacts the gate 622. Because the reflective metal layer is deposited after the light-absorbing dielectric layer 634, the light-absorbing dielectric layer 634 can substantially obstruct portions of the components included in the reflective metal layer, such as the source-drain terminals 642a and 642b and the interconnect 644.

In some implementations, additional layers of material can be deposited and patterned over the reflective metal layer to complete the backplane 600. For example, as shown in FIG. 6K, a planarizing layer 650 can be deposited and patterned over the reflective metal layer. The planarizing layer 650 can include an insulating material, and patterned to define an opening exposing the source-drain terminal 642a and an opening exposing the interconnect 644. Deposition and patterning of the planarizing layer 650 can be followed by the deposition and patterning of a fifth dielectric layer 654. The fifth dielectric layer 654 can include materials similar to those included in the first dielectric layer 610. The fifth dielectric layer 654 can be patterned to define an opening that coincides with the opening in the planarizing layer 650 above the source-drain terminal 642a. A third metal layer can then be deposited over the fifth dielectric layer 654 and patterned to define a first portion of a via 658 contacting the source-drain terminal 642a, an interconnect 662, and an interconnect 666. A second passivation layer 670 can be deposited over the first portion of the via 658, the interconnect 662, and the interconnect 666. The second passivation layer 670 can be patterned to define an opening of the first portion of the via 658. Finally, a transparent conductive layer 674 can be deposited and patterned over the second passivation layer 670 to define a second portion of the via 658 and an interconnect 678.

In some implementations, the first transparent substrate 602 can be coupled to a second transparent substrate 696, as shown in FIG. 6L. As shown, a display element 690 is positioned over the backplane 600 before the first transparent substrate 602 is coupled to the second transparent substrate 696. A light blocking layer 697 is positioned over the second transparent substrate 696 and includes an aperture aligned with the aperture 640 defined in the light-absorbing dielectric layer 634. The display element can be configured to modulate light directed towards the aperture 640 through the aperture in the light blocking layer 697. The display element 690 includes a shutter 691, and two opposing electrostatic actuators 692a and 692b (generally referred to as actuators 692). The actuator 692a includes a looped drive beam 693a and a load beam 694a, and the actuator 692b includes a looped drive beam 693b and a load beam 694b. The drive beams 693a and 693b are fixed to the substrate 602 at one end and run alongside the load beams 694a and 694b. The load beams 694a and 694b are coupled to the shutter at one end and to the first transparent substrate 602 at their other end via an anchor (not shown). Upon application of an actuation voltage across the actuator 692a, the shutter 691 is pulled into a closed position in which it obstructs the aperture 640, as shown in FIG. 6L. The shutter 691 prevents light from a backlight 698 from passing through the aperture 640 in the closed position, as illustrated by the light ray 699. Upon application of an actuation voltage across the actuator 692b, the shutter 691 is pulled into an open position in which it does not obstruct the aperture 640.

In some implementations, the transistor 685 can be configured to control the actuation of the shutter 691, for example by controlling the application or discharging of an actuation voltage to one or both of the actuators 692. The backlight 698 is positioned on the side of the second transparent substrate 696 farthest from the first transparent substrate 602, such that the first transparent substrate 602 is a front substrate of the display device. Together, the first light-absorbing region defined by the light-absorbing conductive layer 606 and the second light-absorbing region defined by the light-absorbing dielectric layer 634 can absorb ambient light passing through the first transparent substrate, thereby preventing such ambient light from being reflected by the reflective components of the backplane 600.

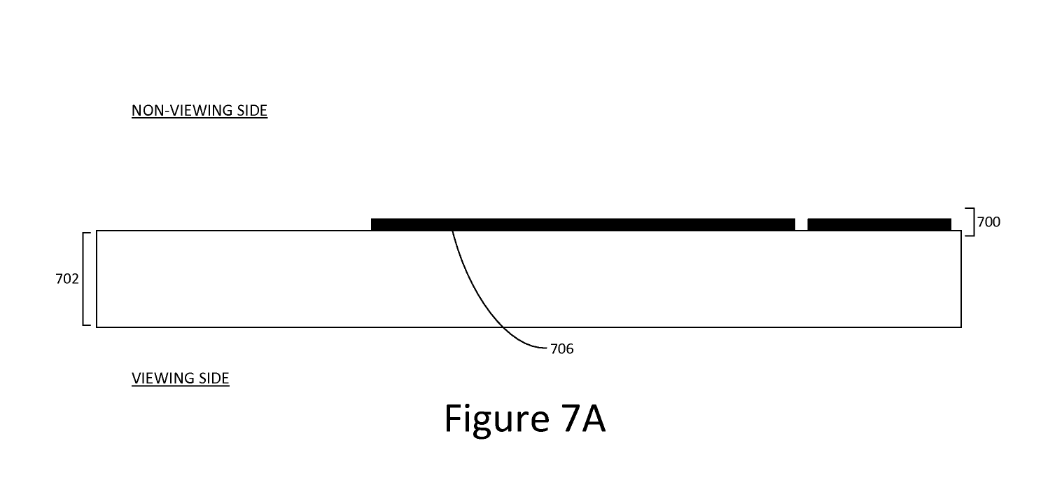

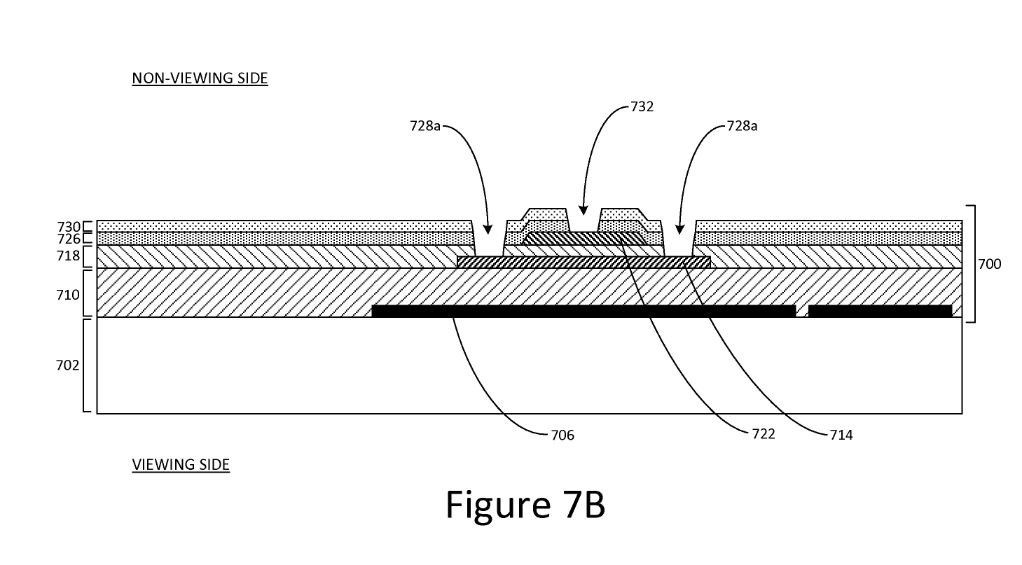

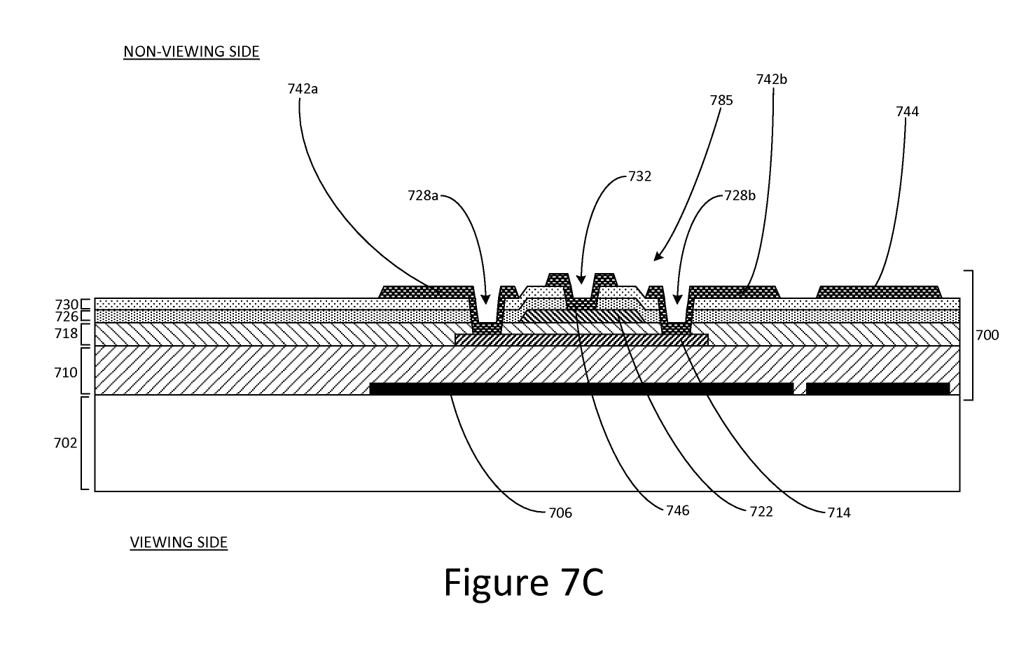

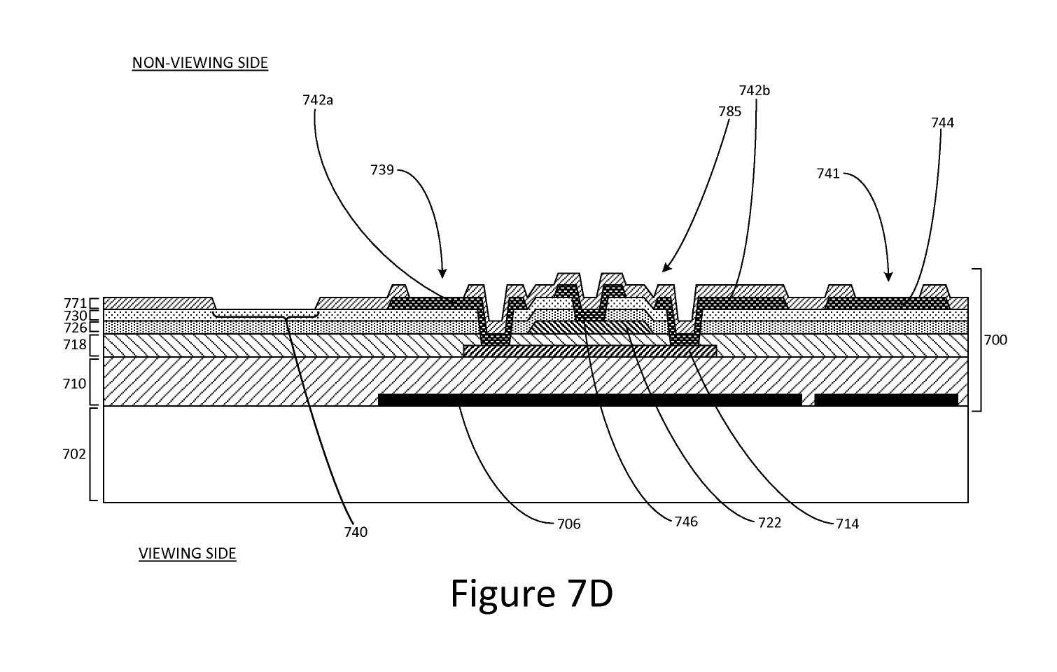

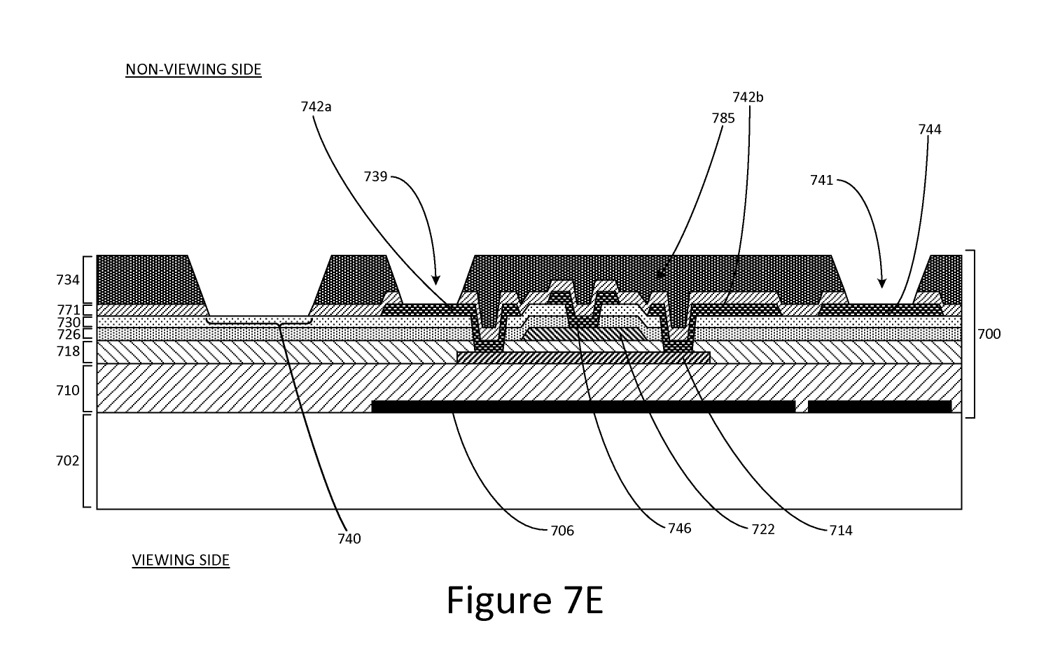

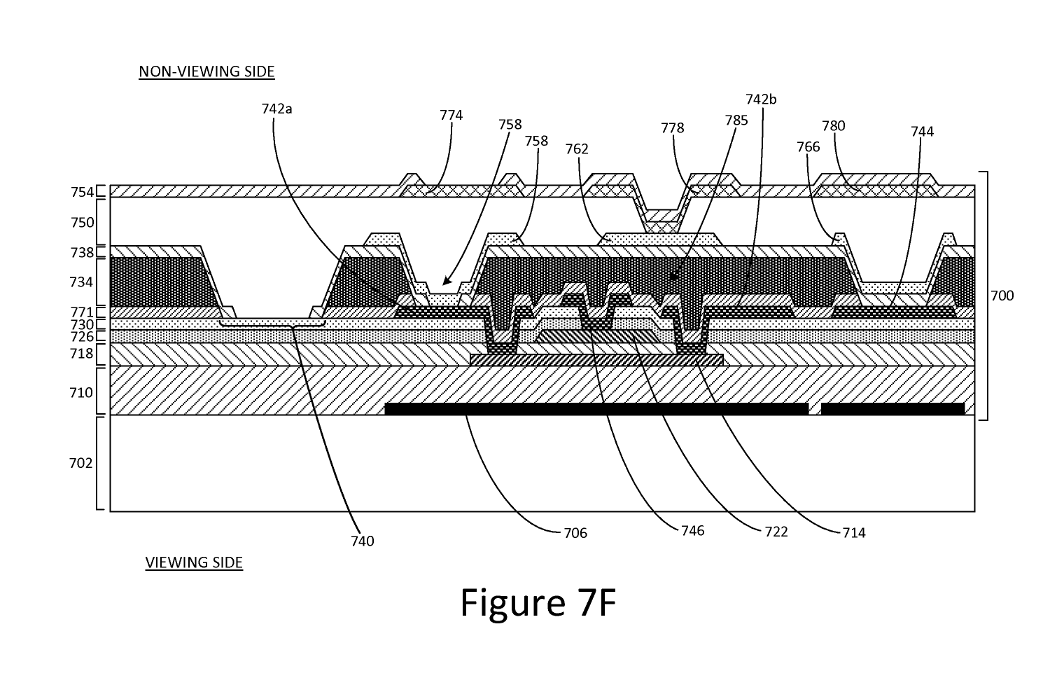

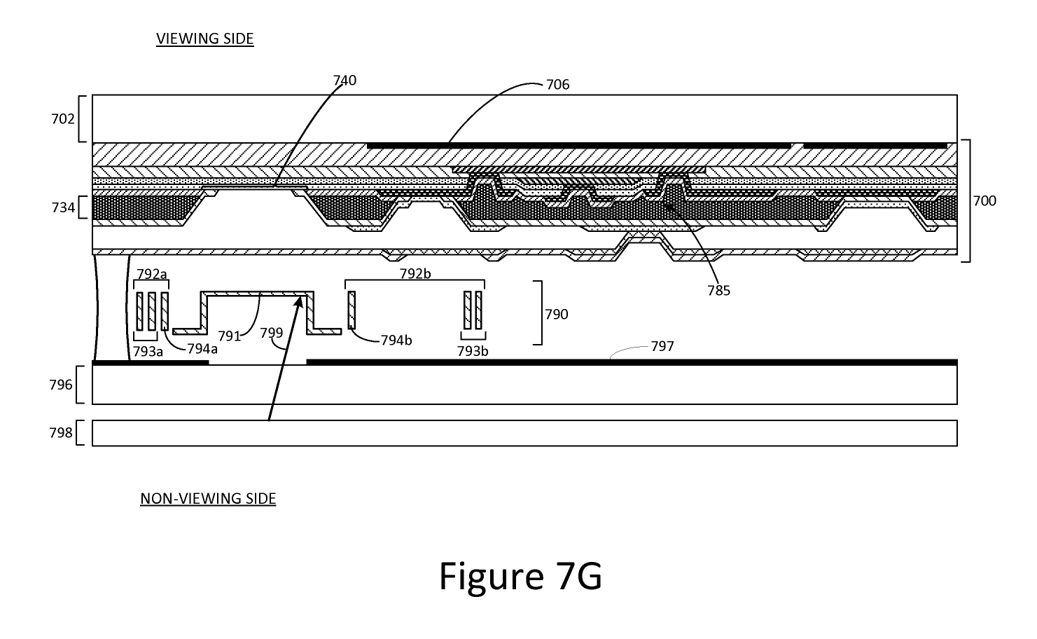

The cross-sectional views of FIGS. 6A-6L show a backplane 600 in which a second reflective metal layer is deposited over the light-absorbing dielectric layer 634 and patterned such that the source-drain terminals 642a and 642b and an interconnect 644 are positioned above the light-absorbing dielectric layer 634 with respect to the first transparent substrate 602. However, as shown in the process 530 of FIG. 5B, the second reflective metal layer can instead be deposited beneath the light-absorbing dielectric material. The manufacturing process 530 of FIG. 5B is discussed further below in connection with FIGS. 7A-7G.

FIGS. 7A-7G show cross-sectional views of stages of construction of another example backplane 700 for a display device that can be manufactured according to the manufacturing process 530 shown in FIG. 5B. The backplane 700 is similar to the backplane 400 shown in FIG. 4, and like reference numerals refer to like elements. The process 530 of FIG. 5B and the manufacturing stages of FIGS. 7A-7G are described together below. In brief overview, the process 530 includes depositing and patterning a light-absorbing conductive layer over a first transparent substrate to define a first light-absorbing region (stage 540), depositing a first dielectric layer over the light-absorbing conductive layer (stage 542), fabricating an LTPS transistor channel over the first light-absorbing region (stage 546), depositing a second dielectric layer over the LTPS transistor channel (stage 548), depositing and patterning a first metal layer to define a transistor gate (stage 550), depositing and patterning third and fourth dielectric layers (stage 552), depositing and patterning a second metal layer to define reflective components of the backplane (stage 554), depositing a first passivation layer over the second metal layer (556), and depositing and patterning a light-absorbing dielectric layer (stage 558).

The process 530 includes depositing and patterning a light-absorbing conductive layer over a first transparent substrate to define a first light-absorbing region (stage 540). For example, as shown in FIG. 7A, the light-absorbing conductive layer 706 can be deposited and patterned over a substrate 702 positioned on a viewing side of the display device. In some implementations, the light-absorbing conductive layer 706 can include any of the materials discussed above in connection with the light-absorbing conductive layer 606 shown in FIGS. 6A-6L. The deposited light-absorbing conductive layer 706 can then be patterned to result in first light-absorbing portion as shown in FIG. 7A. The light-absorbing conductive layer 706 has a larger footprint than the light-absorbing conductive layer 606 shown in FIG. 6. In some implementations, larger footprint of the light-absorbing conductive layer 706 can allow the light-absorbing conductive layer 706 to substantially obstruct reflective components of the backplane 700 that will not covered by the light-absorbing dielectric layer to be deposited in a subsequent stage, due to the positioning of the light-absorbing dielectric layer 734 above the reflective metal layer that will define source-drain terminals 742a and 742b and an interconnect 744. As shown in FIGS. 7A-7G, the light-absorbing conductive layer 706 can define a first light-absorbing region having a footprint that substantially coincides with these components.

FIG. 7B shows the results of several additional steps performed after the deposition and patterning of the light-absorbing conductive layer 706. The steps that have been performed are similar to the steps shown in FIGS. 6B-6G. For example, the stages that have been completed in the cross-sectional view of FIG. 7B include depositing a first dielectric layer 710 over the light-absorbing conductive layer 706 (stage 542), fabricating an LTPS transistor channel 714 over the first light-absorbing region (stage 546), depositing and patterning a second dielectric layer 718 over the LTPS transistor channel 714 (stage 548), depositing and patterning a first metal layer to define a transistor gate 722 (stage 550), and depositing and patterning a third dielectric layer 726 and a fourth dielectric layer 730 (stage 552). The third and fourth dielectric layers 726 and 730 can be patterned to define openings coinciding with the openings 728a and 728b in the second dielectric layer, as well as an opening 732 exposing the gate 722.

A second reflective metal layer can be deposited and patterned to define additional reflective components of the backplane 700 (stage 554). The results of this stage are shown in FIG. 7C. In this example, the reflective components of the control matrix include at least the source-drain terminals 742a and 742b of the transistor 785 and the interconnect 744. In some implementations, the reflective metal layer can include metals such as Al, Cu, Ag, Ni, Cr, and Ti. The reflective metal layer is deposited to fill the openings 728a and 728b in the second dielectric layer 718, as well as the opening 732 in the third dielectric layer 726. The source-drain terminals 742a and 742b contact the channel 714. A gate terminal 746 contacts the gate 722. The reflective metal layer is deposited before the light-absorbing dielectric layer 734. However, due to its relatively large footprint, the light-absorbing conductive layer 706 substantially obstructs the source-drain terminals 742a and 742b, the channel 714, and the interconnect 744.

A first passivation layer 771 can be deposited and patterned over the second metal layer (stage 556). The first passivation layer 771 can be patterned to define an aperture 740, as well as an opening 739 exposing a portion of the source-drain terminal 742a and the an opening 741 exposing a portion of the interconnect 744. The results of this stage are shown in FIG. 7D.

A light-absorbing dielectric layer 734 can be deposited and patterned over the transistor channel 714 to define a second light-absorbing region (stage 558). The results of this stage are shown in FIG. 7E. In some implementations, the light-absorbing dielectric layer 734 can include a light-absorbing polymer material or DSOG. The light-absorbing dielectric layer 734 can be deposited conformally or as a planarization layer. In some implementations, the second light-absorbing region can be selected to correspond to the position of reflective components of the backplane 700 that are not obstructed by the first light-absorbing region defined by the light-absorbing conductive layer 706, such as reflective components included in metal layers that may be deposited after the deposition of the light-absorbing dielectric layer 734. The light-absorbing dielectric layer 734 also can be patterned to define an optical aperture 740 and openings coinciding with the openings 739 and 741 in the first passivation layer 771.

In some implementations, additional layers of material can be deposited and patterned over the light-absorbing dielectric layer 734 to complete the backplane 700. For example, as shown in FIG. 7F, a second passivation layer 738 can be deposited over the light-absorbing dielectric layer 734, and can be patterned to have an openings coinciding with the aperture 740 and the opening 739 in the first passivation layer 771. A third metal layer can then be deposited over the second passivation layer 738 and patterned to define a via 758 contacting the source-drain terminal 742a, an interconnect 762, and an interconnect 766. A planarizing layer 750 can be deposited and patterned to expose a portion of the interconnect 762. A transparent conductive layer can be deposited and patterned over the planarizing layer 750 to define interconnects 774 and 780, and a via 778 contacting the interconnect 762. Finally, a third passivation layer 754 can be deposited over the transparent conductive layer and patterned to expose a portion of the interconnect 774.

In some implementations, the first transparent substrate 702 can be coupled to a second transparent substrate 796, as shown in FIG. 7G. As shown, a display element 790 is positioned over the backplane 700 before the first transparent substrate 702 is coupled to the second transparent substrate 796. A light blocking layer 797 is positioned over the second transparent substrate 796 and includes an aperture aligned with the aperture 740 defined in the light-absorbing dielectric layer 734. The display element can be configured to modulate light directed towards apertures such as the aperture 740. The display element 790 includes a shutter 791, and two opposing electrostatic actuators 792a and 792b (generally referred to as actuators 792). The actuator 792a includes a looped drive beam 793a and a load beam 794a, and the actuator 792b includes a looped drive beam 793b and a load beam 794b. The drive beams 793a and 793b are fixed to the substrate 702 at one end and run alongside the load beams 794a and 794b. The load beams 794a and 794b are coupled to the shutter at one end and to the first transparent substrate 702 at their other end via an anchor (not shown). Upon application of an actuation voltage across the actuator 792a, the shutter 791 is pulled into a closed position in which it obstructs the aperture 740, as shown in FIG. 7G. The shutter 791 prevents light from a backlight 798 from passing through the aperture 740 in the closed position, as illustrated by the light ray 799. Upon application of an actuation voltage across the actuator 792b, the shutter 791 is pulled into an open position in which it does not obstruct the aperture 740.

In some implementations, the transistor 785 can be configured to control the actuation of the shutter 791, for example by controlling the application or discharging of an actuation voltage to one or both of the actuators 792. The backlight 798 is positioned on the side of the second transparent 796 substrate farthest from the first transparent substrate 702, such that the first transparent substrate 702 is a front substrate of the display device. Together, the first light-absorbing region defined by the light-absorbing conductive layer 706 and the second light-absorbing region defined by the light-absorbing dielectric layer 734 can absorb ambient light passing through the first transparent substrate, thereby preventing such ambient light from being reflected by the reflective components of the backplane 700.

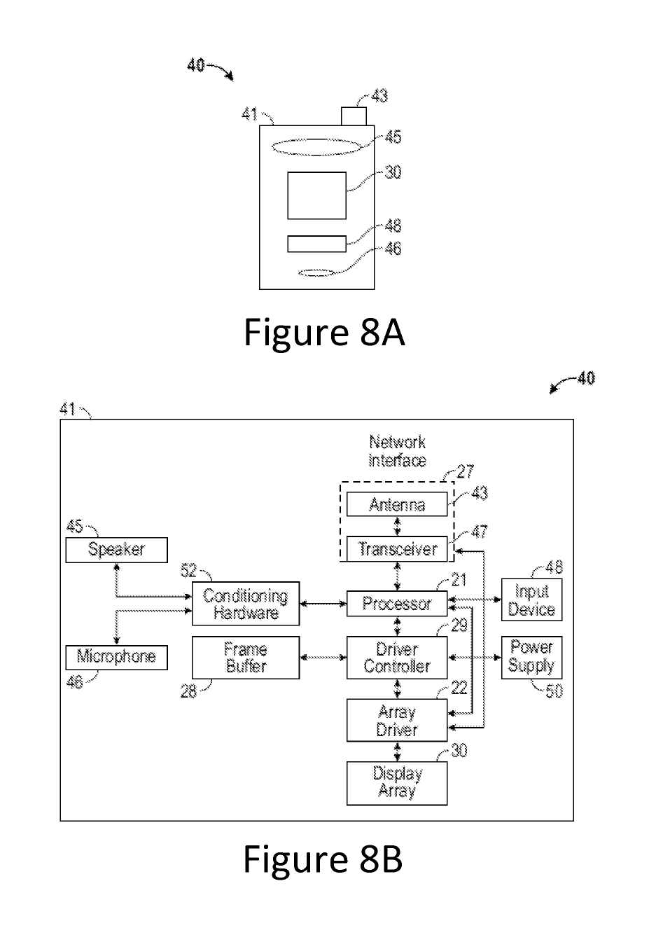

FIGS. 8A and 8B show system block diagrams of an example display device 40 that includes a plurality of display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be capable of including a flat-panel display, such as plasma, electroluminescent (EL) displays, OLED, super twisted nematic (STN) display, LCD, or thin-film transistor (TFT) LCD, or a non-flat-panel display, such as a cathode ray tube (CRT) or other tube device. In addition, the display 30 can include a mechanical light modulator-based display, as described herein.

The components of the display device 40 are schematically illustrated in FIG. 8B. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 8A, can be capable of functioning as a memory device and be capable of communicating with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to any of the IEEE 16.11 standards, or any of the IEEE 802.11 standards. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G, or further implementations thereof, technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29 is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements. In some implementations, the array driver 22 and the display array 30 are a part of a display module. In some implementations, the driver controller 29, the array driver 22, and the display array 30 are a part of the display module.

In some implementations, the driver controller 29, the array driver 22, and the display array 30 are appropriate for any of the types of displays described herein. For example, the driver controller 29 can be a conventional display controller or a bi-stable display controller (such as a mechanical light modulator display element controller). Additionally, the array driver 22 can be a conventional driver or a bi-stable display driver (such as a mechanical light modulator display element controller). Moreover, the display array 30 can be a conventional display array or a bi-stable display array (such as a display including an array of mechanical light modulator display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40. Additionally, in some implementations, voice commands can be used for controlling display parameters and settings.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A display apparatus, comprising:
a transparent substrate having a viewing side and a second side opposite the viewing side; and
a backplane on the second side of the transparent substrate, the backplane including:
a plurality of reflective components including at least a plurality of low-temperature polycrystalline silicon (LTPS) transistor channels;
a light-absorbing dielectric layer positioned on a first side of the LTPS transistor channels farthest from the viewing side of the transparent substrate; and
a light-absorbing conductive layer positioned on a second side of the LTPS transistor channels opposite the first side, wherein the light-absorbing conductive layer has a footprint which includes a first portion that optically obstructs the plurality of LTPS transistor channels from the viewing side of the display.

2. The display apparatus of claim 1, further comprising:
a plurality of transistor gates included within the plurality of reflective components; and
a plurality of source-drain terminals included within the plurality of reflective components.

3. The display apparatus of claim 2, wherein the light-absorbing dielectric layer is positioned between the plurality of LTPS transistor channels and the plurality of source-drain terminals.

4. The display apparatus of claim 2, wherein portions of the light-absorbing dielectric layer are on a side of the plurality of source-drain terminals farthest from the transparent substrate.

5. The display apparatus of claim 1, wherein the light-absorbing dielectric layer optically obstructs a portion of the reflective components included in the backplane from the viewing side of the transparent substrate, and the footprint of the light-absorbing conductive layer extends no more than about 10 microns beyond portions of the footprints of the respective reflective components optically unobstructed by the light-absorbing dielectric layer.

6. The display apparatus of claim 1, wherein:
the reflective components of the backplane have a footprint on the transparent substrate;
the light-absorbing dielectric layer optically obstructs a portion of the footprint of the reflective components from the viewing side of the transparent substrate leaving a portion of the footprint of the reflective components optically unobstructed from the viewing side of the transparent substrate, and
the light-absorbing conductive layer has a footprint that substantially coincides with the portion of the footprint of the reflective components optically unobstructed by the light-absorbing dielectric layer.

7. The display apparatus of claim 1, wherein the light-absorbing dielectric layer is a planarizing layer.

8. The display apparatus of claim 1, wherein the light-absorbing dielectric layer includes dark spin-on-glass (DSOG).

9. The display apparatus of claim 1, wherein the light-absorbing dielectric layer includes a light-absorbing polymer material.

10. The display apparatus of claim 1, wherein the light-absorbing conductive layer comprises at least one of molybdenum (Mo), titanium (Ti), tungsten (W), tantalum (Ta), carbon (C), and carbon black.

11. The display apparatus of claim 1, wherein the light-absorbing dielectric layer defines a plurality of optical apertures each associated with a respective display element.

12. The display apparatus of claim 11, wherein the display elements are MEMS shutter-based display elements.

13. The display apparatus of claim 1, further comprising:
a second transparent substrate coupled to the transparent substrate and positioned on the second side of the transparent substrate; and
a backlight positioned on a side of the second transparent substrate farthest from the transparent substrate.

14. The display apparatus of claim 1, further comprising:
a processor capable of communicating with the display apparatus, the processor being capable of processing image data; and
a memory apparatus capable of communicating with the processor.

15. The display apparatus of claim 13, further comprising:
a driver circuit capable of sending at least one signal to the display apparatus; and
a controller capable of sending at least a portion of the image data to the driver circuit.

16. The display apparatus of claim 13, further comprising:
an image source module capable of sending the image data to the processor, wherein the image source module includes at least one of a receiver, transceiver, and transmitter; and
an input apparatus capable of receiving input data and communicating the input data to the processor.

17. A method of manufacturing a display device, comprising:
depositing and patterning a light-absorbing conductive layer on a transparent substrate on a side of the transparent substrate opposite a viewing side
depositing and patterning a plurality of low-temperature polycrystalline silicon (LTPS) transistor channels over the patterned light-absorbing conductive layer;
depositing and patterning a light-absorbing dielectric layer over the patterned LTPS transistor channels, wherein the patterned light-absorbing conductive layer has a footprint that includes a first portion that optically obstructs the plurality of LTPS transistor channels from the viewing side of the display.

18. The method of claim 17, further comprising:
depositing and patterning a plurality of transistor gates over the LTPS transistor channels; and
depositing and patterning a plurality of source-drain terminals over the LTPS transistor channels.

19. The method of claim 18, wherein the plurality of source-drain terminals are deposited and patterned after the light-absorbing dielectric layer has been deposited and patterned.

20. The method of claim 19, wherein:
the light-absorbing dielectric layer is patterned to optically obstruct a portion of a set of reflective components included in the display device from the viewing side of the transparent substrate, the plurality of reflective components including at least the LTPS transistor channels, the transistor gates, and the source-drain terminals; and
the light-absorbing conductive layer is patterned such that its footprint extends no more than about 10 microns beyond portions of footprints of the reflective components that are optically unobstructed by the light-absorbing dielectric layer.

21. The method of claim 19, wherein:
the display device includes reflective components including the LTPS transistor channels, the source-drain terminals, and the transistor gates, the reflective components having a footprint on the transparent substrate;
the light-absorbing dielectric layer is patterned to optically obstruct a portion of the footprint of the reflective components from the viewing side of the transparent substrate leaving a portion of the footprint of the reflective components optically unobstructed from the viewing side of the transparent substrate, and
the light-absorbing conductive layer is patterned to have a footprint that substantially coincides with the portion of the footprint of the reflective components optically unobstructed by the light-absorbing dielectric layer.

22. The method of claim 18, further comprising depositing and patterning the light-absorbing dielectric layer after the plurality of source-drain terminals have been deposited and patterned.

23. The method of claim 17, wherein the light-absorbing dielectric layer is a planarizing layer.

24. The method of claim 17, wherein the light-absorbing dielectric layer comprises dark spin-on-glass (DSOG).

25. The method of claim 17, wherein the light-absorbing dielectric layer comprises a light-absorbing polymer material.

26. The method of claim 17, wherein the light-absorbing conductive layer comprises at least one of molybdenum (Mo), titanium (Ti), tungsten (W), tantalum (Ta), carbon (C), and carbon black.

27. The method of claim 17, further comprising patterning the light-absorbing dielectric layer to define a plurality of optical apertures each associated with a respective display element.

28. The method of claim 27, further comprising fabricating the display elements on a viewing side of a second transparent substrate facing the transparent substrate.

29. A display apparatus, comprising:
a transparent substrate having a viewing side and a second side opposite the viewing side;
a light-absorbing conductive layer positioned on the second side of the transparent substrate;
a low-temperature polycrystalline silicon (LTPS) transistor channel on a side of the light-absorbing conductive layer farthest from the transparent substrate such that a portion of the light-absorbing conductive layer optically obstructs the LTPS transistor channel from the viewing side of the transparent substrate; and
a light-absorbing dielectric layer coupled to the transparent substrate on a side of the LTPS transistor channel opposite the light-absorbing conductive layer.

30. The display apparatus of claim 29, wherein a footprint of a portion of the light-absorbing conductive layer substantially coincides with a footprint of the LTPS transistor channel.
